(19) United States
(12) Patent Application Publication
(10) Pub. No.: US 2026/0088801 A1
(43) Pub. Date: Mar. 26, 2026

(54) Double-Mode Surface-Acoustic-Wave (DMS) Filter with Apodization

(71) Applicant: RF360 Singapore Pte. Ltd., Singapore (SG)

(72) Inventors: Aimeric Bisognin, Antibes (FR); Charles Binninger, Saint-Jeannet (FR); Aymen Oueslati, Biot (FR); Stefan Ammann, Grosskarolinenfeld (DE); Matthias Pernpeintner, Grafing b. München (DE); Jacques-Antoine Damy, Nice (FR); Thomas Ebner, Munich (DE); Philipp Michael Jaeger, Vaterstetten (DE); Olivier Tristan, Antibes (FR)

(21) Appl. No.: 18/895,108

(22) Filed: Sep. 24, 2024

(51) Int. Cl. H03H 9/64; H03H 3/08; H03H 9/02

(52) U.S. Cl. CPC H03H 9/643; H03H 3/08; H03H 9/02992

(57) ABSTRACT

An apparatus is disclosed for a double-mode surface-acoustic-wave (SAW) filter with apodization. In example aspects, the apparatus includes a double-mode surface-acoustic-wave filter that includes multiple interdigital transducers having multiple fingers. An overlap region of fingers extending from opposite busbars establishes an aperture of the double-mode surface-acoustic-wave filter. The aperture forms an apodized structure across at least part of the double-mode surface-acoustic-wave filter. The multiple interdigital transducers include first and second interdigital transducers. The first interdigital transducer includes a first portion of the apodized structure. The second interdigital transducer includes a second portion of the apodized structure different from the first portion of the apodized structure of the first interdigital transducer. A transition region overlays a border between the first interdigital transducer and the second interdigital transducer. The transition region includes a transition portion of the apodized structure with the transition portion having a non-vanishing slope.

### TECHNICAL FIELD

This disclosure relates generally to wireless transceivers and other components that employ filters and, more specifically, to implementing a double-mode surface-acoustic-wave (DMS) filter with apodization that can be varied across different interdigital transducers (IDTs) of the DMS filter.

### BACKGROUND

Electronic devices use radio-frequency (RF) signals to communicate information. These radio-frequency signals enable users to talk with friends, download information, share pictures, remotely control household devices, and receive global positioning information, just to name a few consumer-oriented examples. To transmit or receive the radio-frequency signals within a given frequency band, the electronic device may use filters to pass signals within the frequency band and to suppress (e.g., attenuate) jammers or noise having frequencies outside of the frequency band. It can be challenging, however, to design a filter that provides filtering for radio-frequency applications, including those that utilize frequencies above 100 megahertz (MHz).

### SUMMARY

An apparatus is disclosed that implements a double-mode surface-acoustic-wave (DMS) filter having apodization properties that can be varied across different interdigital transducers (IDTs) of the DMS filter. With apodization, the length of overlap of neighboring fingers, such as adjacent fingers, varies across the fingers along the length of the DMS filter. In some cases, the lengths of the fingers may be adjusted accordingly to change the amount of overlap. This finger overlap can establish an aperture of the DMS filter. The finger overlap variance can therefore change the size, location, shape, and so forth of the aperture of the DMS filter between two opposite busbars of an IDT thereof. In example implementations, one or more apodization properties can be adjusted on a per-IDT basis. If an apodization is based on a trigonometric function, for instance, the period, phase, or amplitude of the apodization can be different between two IDTs of a DMS, including between two adjacent IDTs. Additionally or alternatively, the slope of the apodization can be realized to be non-vanishing at one or more regions. Example regions that may have a non-zero slope include a transition region at or near a border between two adjacent IDTs and a central region within a given IDT. These techniques can reduce the effect of undesired modes of operation in DMS filters and allow for production of DMS filters with smaller sizes and lower costs. Further, described techniques enable a DMS filter to be constructed using a high-coupling substrate while achieving reduced spurious modes. These and other implementations are described herein.

In an example aspect, an apparatus for filtering is disclosed. The apparatus includes a double-mode surface-acoustic-wave filter that includes multiple interdigital transducers that have multiple fingers. An overlap region of fingers extends from opposite busbars to establish an aperture of the double-mode surface-acoustic-wave filter. The aperture forms an apodized structure across at least part of the double-mode surface-acoustic-wave filter. The multiple interdigital transducers include a first interdigital transducer having a first portion of the apodized structure, with the first portion including one or more first apodization properties. The multiple interdigital transducers also include a second interdigital transducer having a second portion of the apodized structure, with the second portion including one or more second apodization properties different from the one or more first apodization properties of the first interdigital transducer. The multiple interdigital transducers further include a transition region overlaying a border between the first interdigital transducer and the second interdigital transducer. The transition region includes a transition portion of the apodized structure, with the transition portion having a non-vanishing slope.

In an example aspect, an apparatus for filtering is disclosed. The apparatus includes a double-mode surface-acoustic-wave filter that includes multiple interdigital transducers. The multiple interdigital transducers include multiple fingers, with the multiple fingers having various lengths to form an apodized structure across at least part of the double-mode surface-acoustic-wave filter. The multiple interdigital transducers include a first interdigital transducer having a first portion of the apodized structure, with the first portion including one or more first apodization properties. The multiple interdigital transducers also include a second interdigital transducer having a second portion of the apodized structure, with the second portion including one or more second apodization properties different from the one or more first apodization properties. The multiple interdigital transducers further include a transition region overlaying a border between the first interdigital transducer and the second interdigital transducer. The transition region includes a transition portion of the apodized structure, with the transition portion including a phase shift of the apodized structure.

In an example aspect, a method for manufacturing a double-mode surface-acoustic-wave filter is disclosed. The method includes providing multiple interdigital transducers including multiple fingers, with an overlap region of fingers extending from opposite busbars establishing an aperture of the double-mode surface-acoustic-wave filter. The aperture forms an apodized structure across at least part of the double-mode surface-acoustic-wave filter. The method also includes providing a first portion of the apodized structure using a first interdigital transducer of the multiple interdigital transducers, with the first portion including one or more first apodization properties. The method additionally includes providing a second portion of the apodized structure using a second interdigital transducer of the multiple interdigital transducers, with the second portion including one or more second apodization properties different from the one or more first apodization properties of the first interdigital transducer. The method further includes providing a transition portion of the apodized structure. The transition portion overlays a border between the first interdigital transducer and the second interdigital transducer, and the transition portion has a non-vanishing slope.

### BRIEF DESCRIPTION OF DRAWINGS

FIG. 1 illustrates an example operating environment for a double-mode surface-acoustic-wave filter with apodization.

FIG. 2 illustrates an example wireless transceiver including a double-mode surface-acoustic-wave filter that can be apodized.

FIG. 3 illustrates example components of a double-mode surface-acoustic-wave filter that can have one or more apodization properties.

FIG. 4-1 illustrates an example implementation of a double-mode surface-acoustic-wave filter using a thin-film surface-acoustic-wave filter stack that can have an apodized structure.

FIG. 4-2 illustrates an example implementation of a double-mode surface-acoustic-wave filter using a high-quality temperature-compensated surface-acoustic-wave filter stack that can have an apodized structure.

FIG. 5 illustrates an example electrode structure of a double-mode surface-acoustic-wave filter that can include apodization (not shown in FIG. 5).

FIG. 6 illustrates an example double-mode surface-acoustic-wave filter having transition regions that can relate to at least one apodization property (not shown in FIG. 6).

FIG. 7-1 illustrates an example of piston mode structures of an interdigital transducer, which may be part of a double-mode surface-acoustic-wave filter (not depicted in FIG. 7-1).

FIG. 7-2 illustrates an example double-mode surface-acoustic-wave filter that has piston mode structures but lacks apodization.

FIG. 7-3 illustrates an example interdigital transducer having apodization that is realized with varied lengths of an overlap of neighboring fingers.

FIG. 7-4 illustrates an example interdigital transducer having apodization that is realized with varied lengths of an overlap of neighboring fingers, with each finger including at least one piston mode structure.

FIG. 8 illustrates an example double-mode surface-acoustic-wave filter with piston mode structures that comport with an example apodized structure established by varying lengths of finger overlap.

FIGS. 9-1, 9-2, and 9-3 illustrate examples of double-mode surface-acoustic-wave filters with different example trigonometric apodizations.

FIG. 9-4 depicts an enlarged view of a portion of the example double-mode surface-acoustic-wave filter of FIG. 9-3 to illustrate an example phase shift between two adjacent IDTs.

FIG. 10 illustrates an example double-mode surface-acoustic-wave filter having an example apodized structure in which the slope is non-vanishing in one or more regions.

FIGS. 11-1, 11-2, and 11-3 illustrate examples of double-mode surface-acoustic-wave filters with additional example apodizations, including with different example curvilinear characteristics.

FIG. 12-1 illustrates two graphs depicting example real-admittance performance of multiple DMS filters, including examples of DMS filters that lack apodization and examples of DMS filters having apodization as described herein.

FIG. 12-2 illustrates two graphs depicting example admittance-magnitude performance of multiple DMS filters, including examples of DMS filters that lack apodization and examples of DMS filters having apodization as described herein.

FIG. 13 is a flow diagram illustrating an example process for manufacturing a double-mode surface-acoustic-wave filter with apodization.

### DETAILED DESCRIPTION

To transmit or receive radio-frequency signals within a given frequency band, an electronic device may use filters to pass signals within the frequency band and to suppress (e.g., attenuate) jammers or noise having frequencies outside of the frequency band. Electroacoustic devices (e.g., “acoustic filters” or “microacoustic filters”) can be used to filter high-frequency signals in many applications, such as those with frequencies that are greater than 100 megahertz (MHz). An acoustic filter can be tuned to pass certain frequencies (e.g., frequencies within its passband) and attenuate other frequencies (e.g., frequencies that are outside of its passband, such as frequencies within its stopband). Using piezoelectric material as a vibrating medium, the acoustic filter operates by transforming an electrical signal wave that is propagating along an electrical conductor into an acoustic wave (e.g., an acoustic signal wave) that forms across the piezoelectric material, which process can filter certain frequencies. The acoustic wave is then converted back into an electrical filtered signal. The acoustic filter can include an electrode structure that transforms or converts between the electrical waves and the acoustic waves.

The acoustic wave forms across the piezoelectric material and has a velocity with a magnitude that is significantly less than a velocity of an electromagnetic wave. Generally, the magnitude of the velocity of a wave is proportional to a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as mobile phones.

Double-mode surface-acoustic-wave (SAW) (DMS) filters can include, for example, multiple (e.g., three, four, five, seven, or more) interdigital transducers (IDTs) laid out in a symmetric track with reflectors at both ends. There is a border between any two adjacent IDTs, which can be referred to as a cavity at the transition of the two IDTs. A propagating acoustic wave excites multiple modes of the DMS filter as part of the propagation of the acoustic signal wave across multiple IDTs of the DMS filter. These modes may correspond to displacement fields that arise, for example, at different portions of the individual IDTs, at the transitions between adjacent IDTs, or across two or more IDTs of the DMS filter.

Thus, double-mode surface-acoustic-wave (DMS) filters can have one or more (e.g., two or three) main modes that are excited as part of passband filtering. DMS filters can also have, however, one or more spurious modes that negatively impact performance. Generally, it can be challenging to design a wideband acoustic filter with a compact design that can provide adequate suppression of spurious modes (e.g., an undesired mode such as a trap mode) within a passband of the wideband acoustic filter. To achieve a compact design, some techniques use a DMS filter, which can have a smaller footprint as compared to other types of acoustic filters. By itself, however, the DMS filter might not be able to attenuate spurious modes within the passband by a desired amount. To address these spurious passband modes, some filter architectures use multiple resonators, such as multiple surface-acoustic-wave (SAW) filters arranged in a ladder-type structure. These additional filters can significantly increase the overall footprint of a wireless transceiver, which adds costs and can make it challenging to integrate within space-constrained devices.

Other techniques may attempt to attenuate a spurious mode within the passband by customizing a geometric property of the electrode structure, e.g., within a transition region of the DMS filter. In some instances, however, it can be challenging to manufacture the electrode structure with a desired geometric property. Additionally or alternatively, desired geometries of an electrode structure may be disadvantageous for other reasons, such as fabrication stability, sensitivities, nonlinearity, or power durability.

To address these challenges, one-dimensional (1D) techniques can be employed for implementing a DMS filter having a transition region with a partly uniform geometric property. A value of the geometric property of the fingers within the transition region may be different than a value of the geometric property across other sets of fingers outside of the transition region. Examples of such geometric properties include a pitch and a metallization ratio.

These geometric properties can be adjusted along a one-dimensional line that extends longitudinally along the propagation direction of a wave traveling across the DMS filter. This adjustment can enable the suppression of spurious modes within the passband. In these ways, the DMS filter can be better integrated within space-constrained devices and can realize sufficient spurious mode suppression in the passband with fewer additional resonators, if any.

A DMS filter can also have, however, two-dimensional (2D) modes that adversely impact filtering performance, such as the frequency response of a bandpass filter. The frequency response of a bandpass filter can resemble the shape of the letter “n” with a graph of attenuation versus frequency. The top of the letter “n” roughly corresponds to a passband of the bandpass filter. The frequencies outside of the letter “n” roughly correspond to the stopband of the filter. The sides of the letter “n” are typically slanted in the zones transitioning between the passband and the lower and upper portions of the stopband. The slanted portion of the graph is sometimes referred to as the skirt of the frequency response.

The 2D modes can cause the frequency response to have relatively smaller-scale peaks (spikes) and valleys instead of forming a relatively smooth “n” shape. These rises and dips deteriorate the output signal of a DMS filter by causing nearby frequencies of an input signal to have noticeably different responses at the output signal. At least some of these rises and dips in the frequency response are caused by 2D modes of a DMS filter: the transversal modes or the trap modes. The displacement fields caused by these two spurious modes interact with the desirable main modes primarily in the trap barrier regions.

Each trap barrier region lies around the distal tips of fingers of the comb-shaped structures that form an interdigital transducer (IDT). In some designs, these distal tips of the fingers are arrayed in a straight, uncurving line. Additionally, these distal tips are positioned at a constant distance from a busbar of one (or two) comb-shaped structures. Further, the straight lines formed by the distal tips and the constant distance to the busbar(s) produces an aperture of constant width along the transversal direction. This is because the aperture of the DMS filter corresponds to a distance between the distal tips of fingers (e.g., adjacent fingers) from opposite busbars of the two comb-shaped IDT structures or the overlap of fingers extending from the opposite busbars.

To counteract the negative effects of the 2D spurious modes, this document describes multiple implementations that employ apodization. Apodization changes the positions of the distal tips of fingers, such as in accordance with one or more functions. The changes to the positions of the distal tips of fingers results in changes to an overlap region between two or more fingers, such as pairs of adjacent fingers. Thus, the aperture of the DMS filter can be changed in these manners. By way of example only, an apodization schema can form the distal tips of fingers into a sine wave or another trigonometric function. Additionally, the apodization function can be based on triangular or step functions; this includes being based on triangular and step functions in accordance with a permitted herein, but optional, interpretation of “or” as an inclusive-or term.

The apodization schema can also or instead be applied to piston mode structures of the fingers of the IDTs. Each piston mode structure can be created, for example, by changing a structural aspect of the finger, such as a mass or shape of the finger. Other examples of piston mode structures are described herein below. Piston mode structures can be fabricated at the distal tips of fingers, such as by increasing a mass or surface area of the fingertip. Piston mode structures can also be fabricated near the origin of fingers and positioned proximate to the distal tips of two adjacent fingers, and thus proximate to the piston mode structures in some cases of the two adjacent fingers, extending from an opposite busbar. Therefore, in at least some of such cases, each finger has two piston mode structures. The piston mode structures can be fabricated to produce an apodized structure across at least part of a DMS filter. Other approaches to apodization are described herein.

In example implementations, an apodization function can be individualized for each IDT of a DMS filter. For instance, each IDT of multiple IDTs of the DMS filter may have at least one different apodization property relative to one or more other IDTs of the multiple IDTs. With respect to a sine or cosine function apodization, each IDT can have a different period, a different phase shift, or a different magnitude apodization property, just to name a few examples. In some cases, a slope of the apodized structure can be non-vanishing (e.g., non-zero) in one or more regions as at least one apodization property is varied across at least a portion of the multiple IDTs. Examples of such regions include a transition region that borders two adjacent IDTs, a central portion of an individual IDT, a combination thereof, and so forth. Additionally or alternatively, two different apodization properties for two adjacent IDTs can cause a phase shift of the apodized structure to be present at the border between the two adjacent IDTs. Establishing an apodized structure with a non-zero slope in particular regions can average or smooth out unwanted excitation modes to reduce the production of spurious artifacts in the frequency response.

Described implementations for varying the apodization of a DMS filter within the multiple IDTs thereof can be applied to DMS filters having different substrates. By way of example only, a high-coupling substrate can be used because the described techniques reduce the effects of spurious modes, which high-coupling substrates are more likely to produce. An example of a high-coupling substrate is Lithium niobate (LiNbO₃), such as a piezoelectric layer of Lithium niobate (LiNbO₃) having a cut approximately between 145° and 180°. Here, “approximately” can connote a deviation from a given parameter by 10%, 5%, or even 3% or less. Described implementations for varying the apodization of a DMS filter within the multiple IDTs thereof can be applied to DMS filters having relatively smaller apertures. As the aperture becomes smaller, the relative size of the negative effects of the trap region increase. These trap region effects can be reduced by employing the apodization techniques that are described herein, thereby enabling smaller and less costly filters to be used.

In these manners, a DMS filter can include multiple IDTs having different apodization properties relative to each other to reduce at least the 2D spurious modes. The techniques described herein for reducing the 2D spurious modes can be used in conjunction with, or separate from, those techniques for reducing 1D spurious modes as described above. In either case, the techniques described herein for employing apodization variations can smooth the frequency response of a filter device having at least one DMS filter.

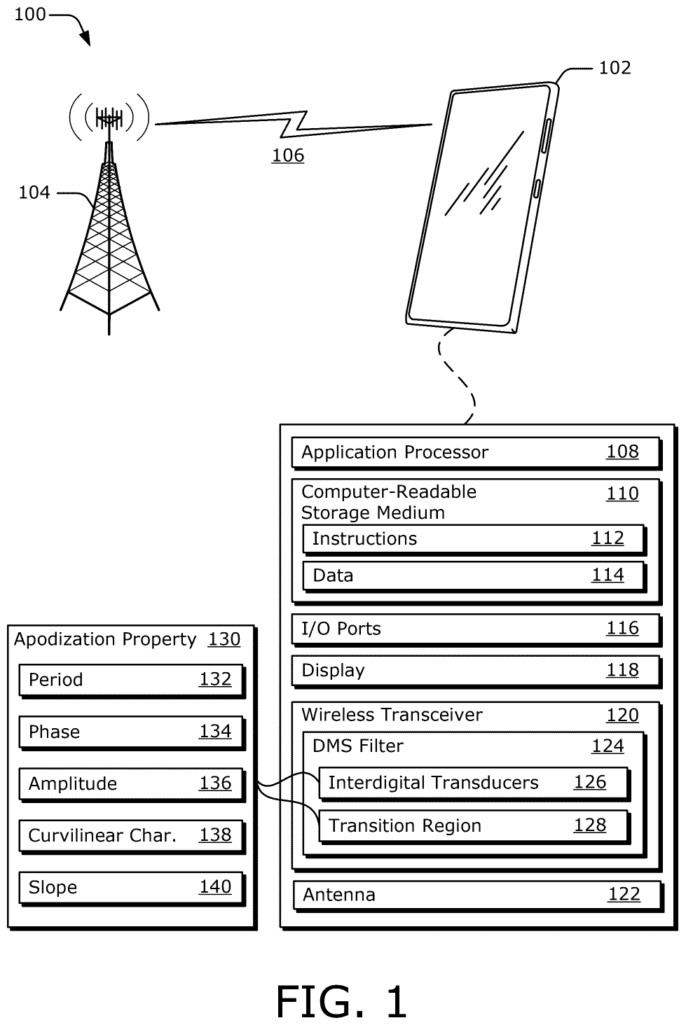

FIG. 1 illustrates an example environment 100 for operating a double-mode surface-acoustic-wave filter 124 with apodization. In the environment 100, an example computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6th-generation (6G) cellular (e.g., of the 3rd Generation Partnership Project (3GPP)); IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor or central processing unit (CPU), that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 via the antenna 122. Although not shown, the wireless transceiver 120 can be coupled to a communication processor, such as a wireless modem.

In the example shown in FIG. 1, the wireless transceiver 120 includes at least one double-mode surface-acoustic-wave filter 124 (DMS filter 124). The double-mode surface-acoustic-wave filter 124 can be implemented as, for example, a longitudinal-coupled double-mode surface-acoustic-wave (LDMS) filter. The double-mode surface-acoustic-wave filter 124 can be implemented using, for example, a thin-film surface-acoustic-wave (TFSAW) filter stack or a high-quality temperature-compensated surface-acoustic-wave (HQTC SAW) filter stack. In general, the double-mode surface-acoustic-wave filter 124 can excite at least two wave modes. By way of example only, the double-mode surface-acoustic-wave filter 124 can excite a main wave mode (e.g., a plate mode) and a cavity mode.

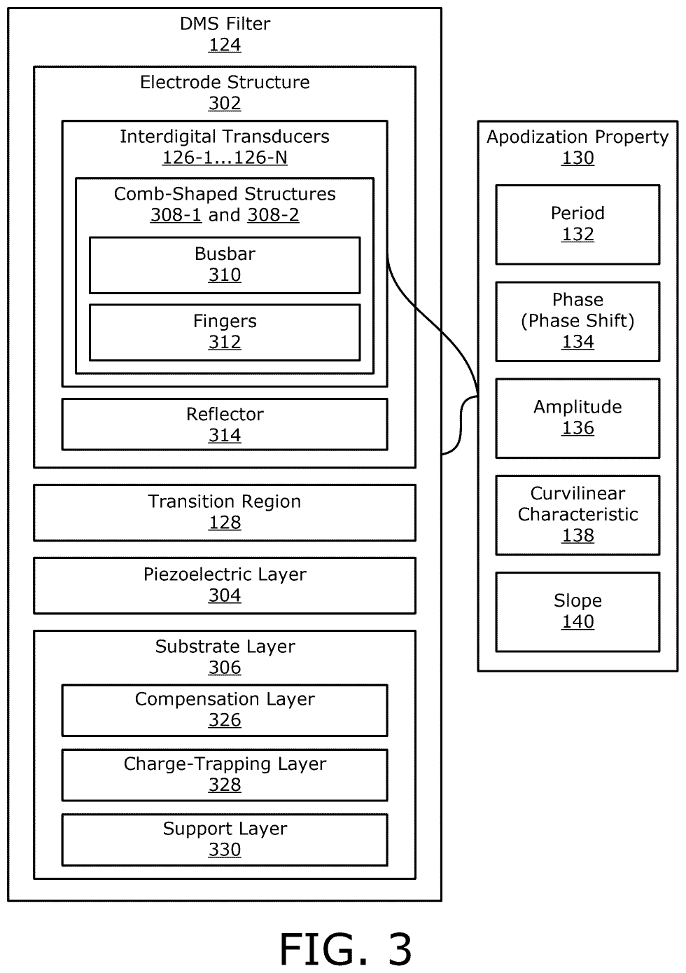

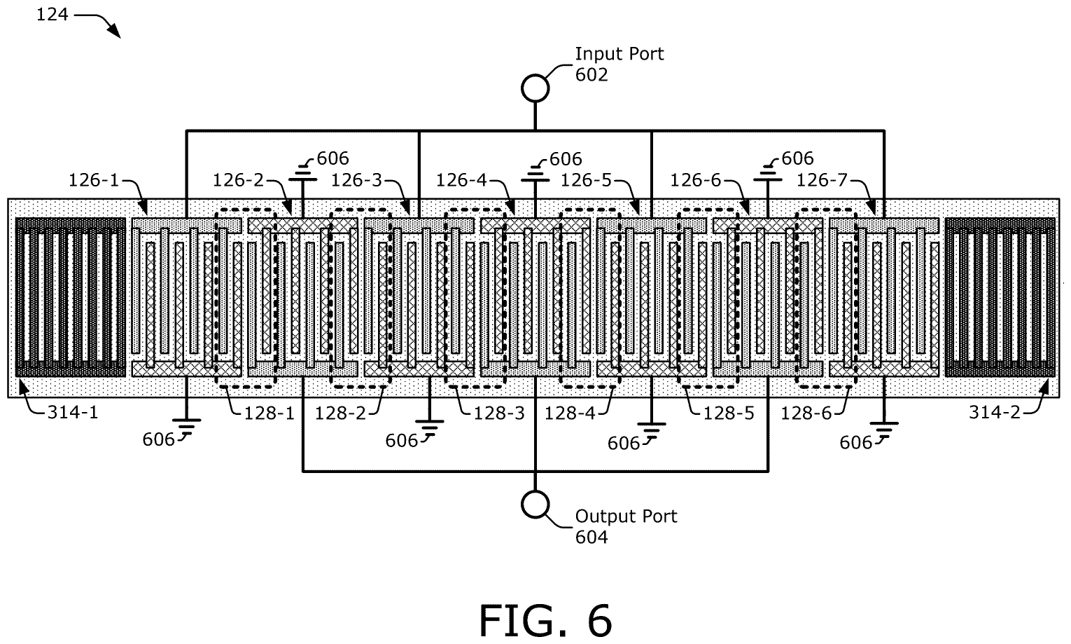

The double-mode surface-acoustic-wave filter 124 includes at least two interdigital transducers 126 and at least one transition region 128. A transition region 128 may be present between two adjacent interdigital transducers 126, span parts of two adjacent interdigital transducers 126, some combination thereof, and so forth. Additionally or alternatively, although the rectangle representing the transition region 128 is depicted separately from the interdigital transducers 126 in FIG. 1, each interdigital transducer 126 may include at least one transition region 128, or portion thereof. Examples of interdigital transducers 126 and transition regions 128 are further described with respect to FIGS. 3 and 6.

Each interdigital transducer 126 can include at least one apodization property 130 or at least part of an apodized structure that includes or exhibits the at least one apodization property 130. Further, at least one apodization property 130 of each of the interdigital transducers 126 can be different from at least one apodization property 130 of one or more other interdigital transducers 126, including at least one adjacent interdigital transducer 126. In some cases, the apodization property 130 is present at least within a transition region 128. The apodization property 130 may pertain, for instance, to an overlap region between fingers, to the distal tips of fingers of the interdigital transducers 126 (e.g., including piston mode structures that are disposed on the fingers at least near the distal tips or proximate to origins of the fingers), a combination thereof, and so forth.

Examples of an apodization property 130 include at least one period 132, at least one phase 134 (or phase shift 134), at least one amplitude 136, at least one curvilinear characteristic 138, at least one slope 140, and so forth. Thus, an apodization property 130 can relate to a trigonometric function, a step function, a triangular function, a piecewise linear function, a differentiable function, and so forth. A common or same apodization property 130 may also extend across multiple interdigital transducers 126, including up to all interdigital transducers 126 of a given DMS filter 124.

Implementing a DMS filter 124 having an apodized structure as described herein can be advantageous in multiple environments and for a variety of reasons. Employing DMS filters 124 becomes more feasible in the context of enabling an increasing number of frequency bands by using high-coupling materials because high-coupling materials can enable both lower costs and reduced size for wide-bandwidth filters. The described apodization techniques enable use of high-coupling materials, which naturally produce more spurious modes, by “flattening” the peaks and valleys caused by the spurious modes to thereby smooth the resulting frequency response of the filter. At least some of the described apodization techniques counteract spurious modes present in the trap regions of a DMS filter. Because these trap-region-related spurious modes become worse as the aperture of a DMS filter decreases, the described apodization techniques support using DMS filters with smaller apertures. Thus, the described techniques can, for instance, produce wideband filters that offer better performance than equal-cost filters that do not employ these techniques.

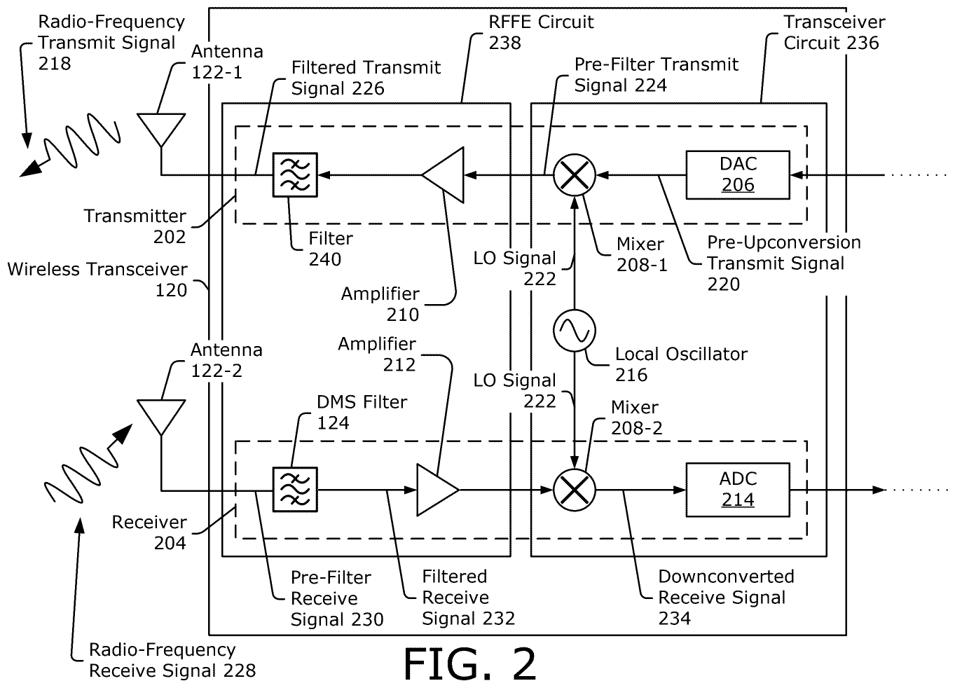

Generally, a double-mode surface-acoustic-wave filter 124 can be implemented as a wideband filter. For instance, a bandwidth of the double-mode surface-acoustic-wave filter 124 can be greater than (including greater than or equal to) approximately 4% of a center frequency of its passband. In some implementations, this bandwidth enables the double-mode surface-acoustic-wave filter 124 to filter frequencies associated with multiple frequency bands. Examples of the wireless transceiver 120 are described next with respect to FIG. 2.

FIG. 2 illustrates an example wireless transceiver 120 including a double-mode surface-acoustic-wave filter 124 that can include an apodized structure. Generally, the wireless transceiver 120 can communicate a wireless signal via the at least one antenna 122. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one filter 240. The filter 240 can be implemented as an acoustic filter, which may be a bandpass filter as depicted.

The receiver 204 includes at least one double-mode surface-acoustic-wave filter 124, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem or a baseband or communications processor). The digital-to-analog converter 206 of the transmitter 202 or the analog-to-digital converter 214 of the receiver 204 can also or instead be incorporated as part of a processor.

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across such circuits in these implementations. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 or the analog-to-digital converter 214 can be implemented on another separate circuit that may include the application processor 108 or the modem. The radio-frequency front-end circuit 238 includes the amplifier 210 of the transmitter 202, the filter 240 of the transmitter 202, the double-mode surface-acoustic-wave filter 124 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and may include some noise or unwanted frequencies, such as a harmonic frequency. The amplifier 210 amplifies the pre-filter transmit signal 224 and passes the amplified pre-filter transmit signal 224 to the filter 240.

The filter 240 filters the amplified pre-filter transmit signal 224 to generate a filtered transmit signal 226. As part of the filtering process, the filter 240 attenuates the noise or unwanted frequencies within the pre-filter transmit signal 224. The transmitter 202 provides the filtered transmit signal 226 to the antenna 122-1 for transmission. The emanated or transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The double-mode surface-acoustic-wave filter 124 accepts the received radio-frequency receive signal 228, which is represented by a pre-filter receive signal 230. The double-mode surface-acoustic-wave filter 124 filters noise or unwanted frequencies within the pre-filter receive signal 230 to generate a filtered receive signal 232. As described herein (e.g., with reference to FIGS. 3, 5, and 6), the double-mode surface-acoustic-wave filter 124 (e.g., as a receive filter of the receiver 204) can include at least one DMS track. A receive filter can, however, include at least one DMS track and one or more other acoustic elements (e.g., microacoustic resonators).

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem or the baseband or communications processor). Although the wireless transceiver 120 is depicted with one mixer 208 in each of the transmitter 202 and the receiver 204, the wireless transceiver 120 can alternatively be realized with a superheterodyne architecture.

Generally, FIG. 2 illustrates one example configuration of the wireless transceiver 120. Other configurations of the wireless transceiver 120 can support multiple frequency bands or share an antenna 122 across multiple transceivers. One of ordinary skill in the art can appreciate the variety of other configurations for which the double-mode surface-acoustic-wave filter 124 may be included. For example, the double-mode surface-acoustic-wave filter 124 can be integrated within a duplexer or diplexer of the wireless transceiver 120. Also, some implementations of the wireless transceiver 120 can implement the filter 240 of the transmitter 202 using a double-mode surface-acoustic-wave filter 124. Additionally, a double-mode surface-acoustic-wave filter 124 can be implemented in a computing device 102 (of FIG. 1) outside of a wireless transceiver 120. Example implementations of a double-mode surface-acoustic-wave filter 124 are described next with reference to FIG. 3.

FIG. 3 illustrates example components of a double-mode surface-acoustic-wave filter 124 that can have one or more apodization properties. In the depicted configuration, the example double-mode surface-acoustic-wave filter 124 includes an electrode structure 302, a piezoelectric layer 304, and at least one substrate layer 306. The electrode structure 302 comprises an electrically conductive material, such as metal, to form electrode(s) and can include one or more layers. The one or more layers can include one or more metal layers and can optionally include one or more adhesion layers. As an example, the metal layers can be composed of aluminium (Al), copper (Cu), silver (Ag), gold (Au), tungsten (W), platinum (Pt), or some combination or doped version thereof. The adhesion layers can be composed of, for example, chromium (Cr), titanium (Ti), molybdenum (Mo), or some combination thereof.

The electrode structure 302 can include two or more interdigital transducers 126-1, 126-2, . . . 126-N, with N being an integer greater than one in this context. The interdigital transducers 126-1 . . . 126-N convert an electrical signal into an acoustic wave and convert the acoustic wave into a filtered electrical signal. Each interdigital transducer 126 includes at least two comb-shaped structures 308-1 and 308-2. Each comb-shaped structure 308-1 and 308-2 includes a busbar 310 (e.g., a conductive segment or rail) and multiple fingers 312 (e.g., electrode fingers). The electrode structure 302 can also optionally include two or more reflectors 314. In an example implementation, the multiple interdigital transducers 126-1 to 126-N are arranged between two reflectors 314. The reflectors 314 reflect the traveling acoustic wave back towards the multiple interdigital transducers 126-1 to 126-N. Examples of the electrode structure 302 and the interdigital transducers 126-1 . . . 126-N are further described with respect to FIGS. 4-1 to 6.

One or more physical characteristics of the interdigital transducers 126-1 . . . 126-N can be characterized by the apodization property 130. In particular, the apodization property 130 can describe the positioning, arrangement, patterning, and/or physical characteristic(s) (e.g., length) of the fingers 312, including a portion thereof, within the electrode structure 302. Example apodization properties 130 include the period 132, the phase 134, the amplitude 136, the curvilinear characteristic 138, and the slope 140. These apodization properties 130 can vary across the electrode structure 302 on an individual property basis or in concert with one another, and within a single interdigital transducer 126 or across multiple interdigital transducers 126-1 . . . 126-N.

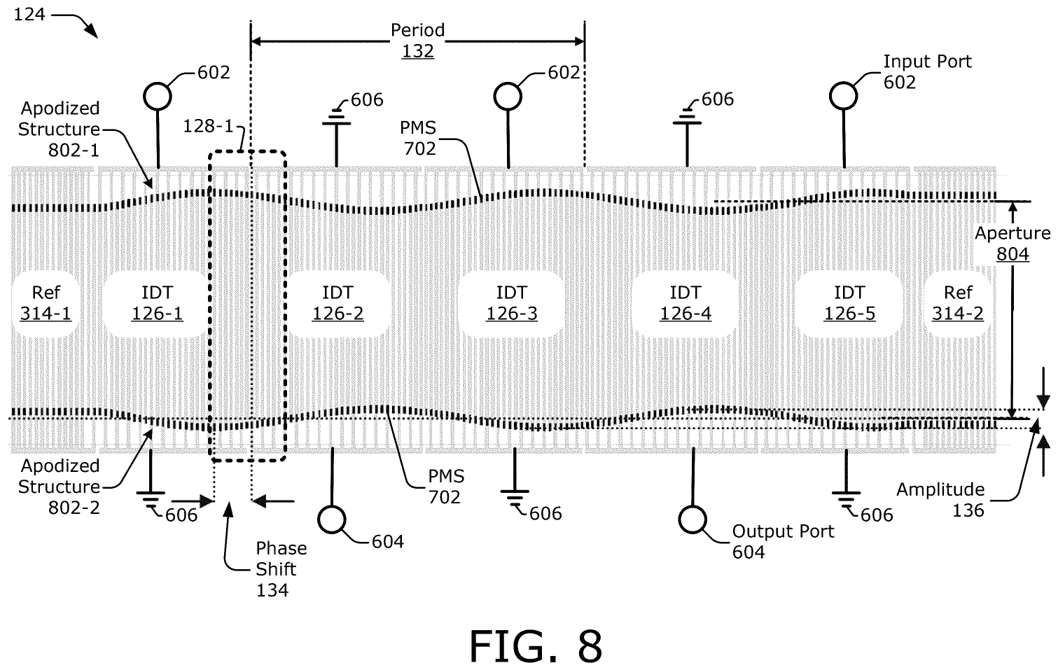

In some cases, the transition region 128 represents one or more sets of fingers 312 respectively positioned at adjacent outer edges of two adjacent interdigital transducers (e.g., IDTs 126-1 and 126-2). However, a transition region 128 can also or instead represent one or more sets of fingers 312 present within a single interdigital transducer 126. Examples of the transition region 128 are further described with respect to FIGS. 5 and 6. FIG. 8 and subsequent figures depict examples of different combinations of apodization properties 130 for different sets of fingers 312 for one or more interdigital transducers 126.

In example implementations, the piezoelectric layer 304 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), quartz, aluminium nitride (AlN), aluminium scandium nitride (AlScN), or some combination thereof. In general, the material that forms the piezoelectric layer 304 can have a crystalline structure. This crystalline structure is defined by an ordered arrangement of particles (e.g., atoms, ions, or molecules). In some implementations, the piezoelectric layer 304 has an electromechanical coupling factor (k²) that is greater than or equal to approximately 4%. By way of example only, a high coupling (k²) material can have a coupling coefficient approximately between 5% and 20%.

The substrate layer 306 includes one or more sublayers that can support passivation, temperature compensation, power handling, mode suppression, and so forth. As an example, the substrate layer 306 can include at least one compensation layer 326, at least one charge-trapping layer 328, at least one support layer 330, or some combination thereof. These sublayers can be considered part of the substrate layer 306 or their own separate layers.

The compensation layer 326 can provide temperature compensation to enable the double-mode surface-acoustic-wave filter 124 to achieve a target temperature coefficient of frequency based on the thickness of the piezoelectric layer 304. In some implementations, a thickness of the compensation layer 326 can be tailored to provide mode suppression (e.g., suppress a spurious plate mode). In example implementations, the compensation layer 326 can be implemented using at least one silicon dioxide (SiO₂) layer, at least one doped silicon dioxide layer, at least one silicon nitride layer, at least one silicon oxynitride layer, or some combination thereof. In some applications, the substrate layer 306 may not include, for instance, the compensation layer 326 to reduce cost of the double-mode surface-acoustic-wave filter 124.

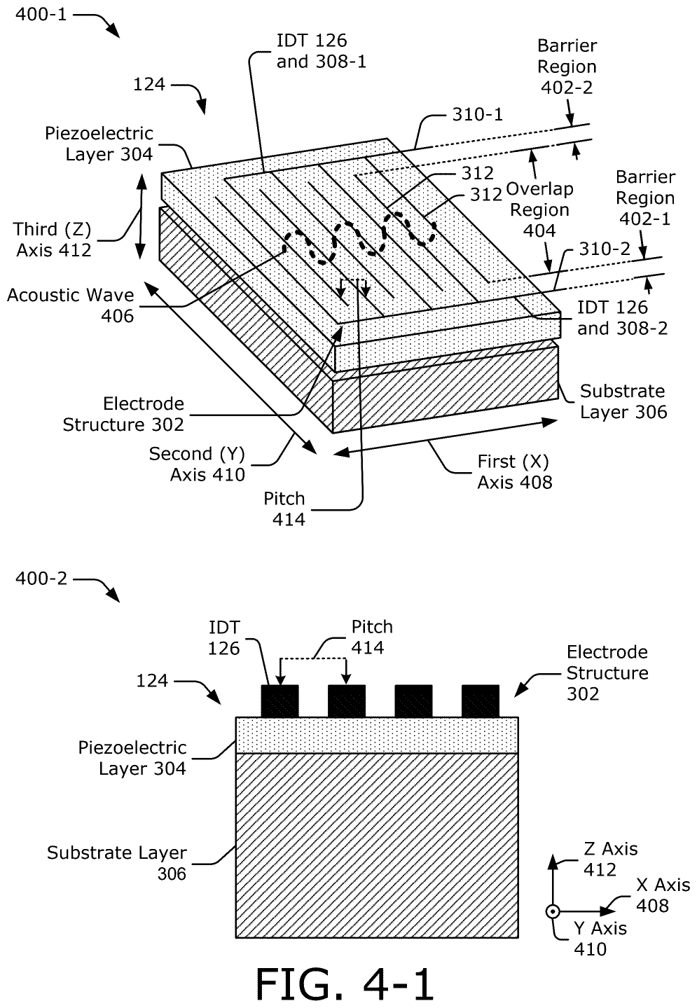

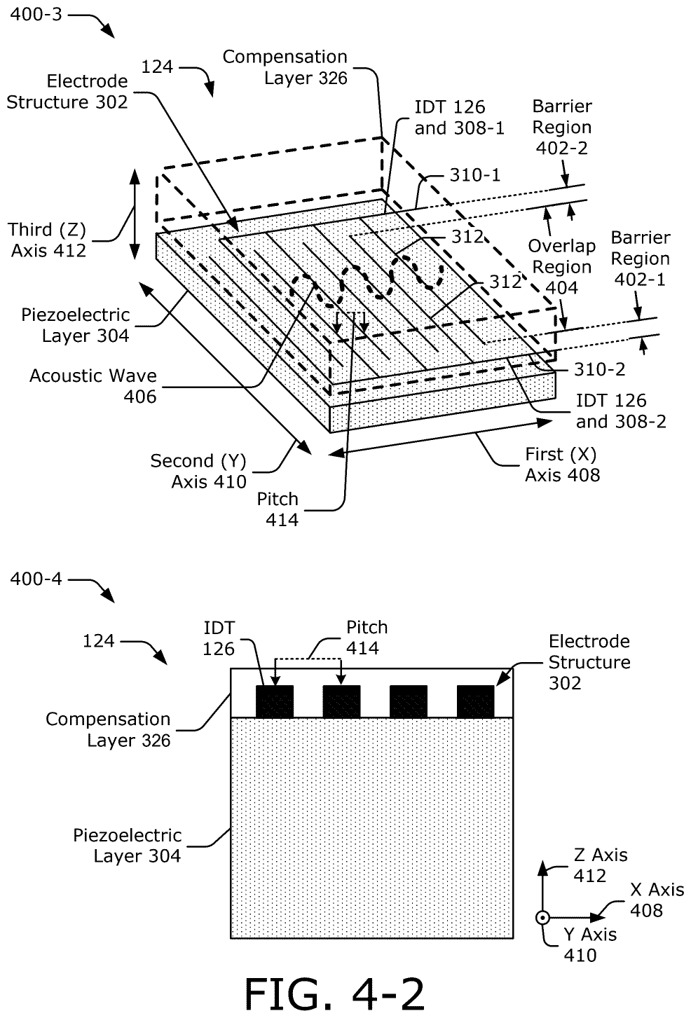

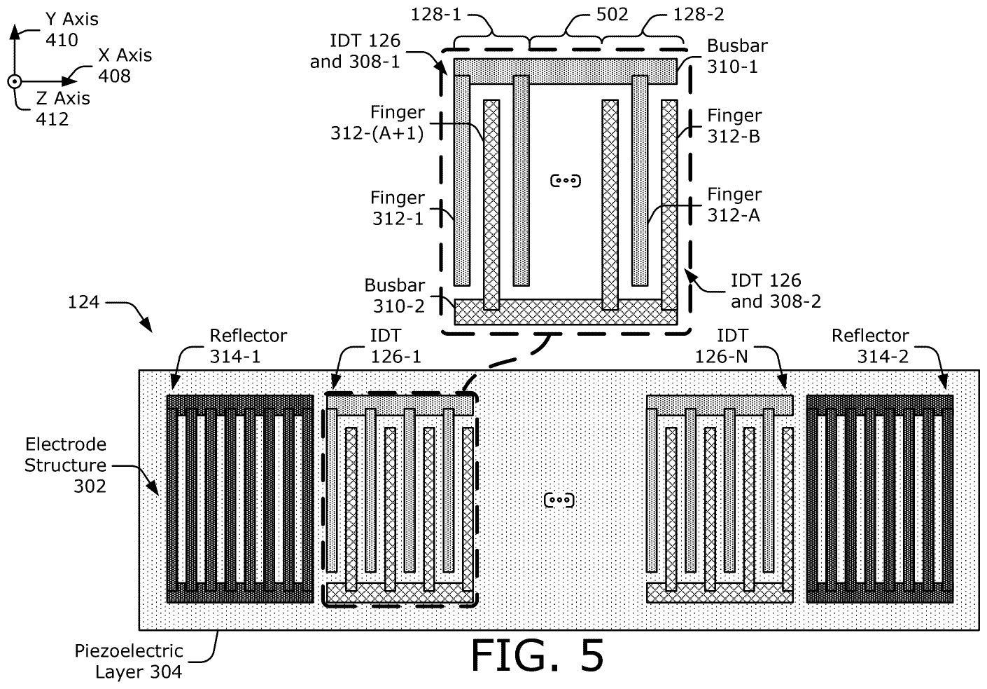

Generally, the techniques for implementing a double-mode surface-acoustic-wave filter 124 having at least one transition region 128 with different apodization properties 130 can apply to different types of DMS filters. For example, these techniques can be employed with filter stacks that do not include a compensation layer 326 (e.g., the thin-film surface-acoustic-wave filter stack of FIG. 4-1) and filter stacks that include the compensation layer 326 (e.g., the high-quality temperature-compensated filter stack of FIG. 4-2).

The charge-trapping layer 328 can trap induced charges at the interface between the compensation layer 326 and the support layer 330 in order to, for instance, suppress nonlinear substrate effects. The charge-trapping layer 328 can include at least one polysilicon (poly-Si) layer (e.g., a polycrystalline silicon layer or a multicrystalline silicon layer), at least one amorphous silicon layer, at least one silicon nitride (SiN) layer, at least one silicon oxynitride (SiON) layer, at least one aluminium nitride (AlN) layer, diamond-like carbon (DLC), diamond, or some combination thereof.

The support layer 330 can enable the acoustic wave to form across the surface of the piezoelectric layer 304 and reduce the amount of energy that leaks into the substrate layer 306. In some implementations, the support layer 330 can also act as a compensation layer 326. In general, the support layer 330 is composed of material that is nonconducting and provides isolation. For example, the support layer 330 can be formed using silicon (Si) material (e.g., a doped high-resistive silicon material), sapphire material (e.g., aluminium oxide (Al₂O₃)), silicon carbide (SiC) material, fused silica material, quartz, glass, diamond, or some combination thereof. In some implementations, the support layer 330 has a relatively similar thermal expansion coefficient (TEC) as the piezoelectric layer 304. The support layer 330 can also have a particular crystal orientation to support the suppression or attenuation of spurious modes.

In some cases, the double-mode surface-acoustic-wave filter 124 can be connected to other resonators associated with the same or different layer stacks than the double-mode surface-acoustic-wave filter 124. Examples of the electrode structure 302, the piezoelectric layer 304, and the substrate layer 306 are described next with respect to FIGS. 4-1 and 4-2.

FIG. 4-1 illustrates an example implementation of a double-mode surface-acoustic-wave filter 124 using a thin-film surface-acoustic-wave (TF-SAW or TFSAW) filter stack that can have an apodized structure. A three-dimensional perspective view 400-1 of the double-mode surface-acoustic-wave filter 124 is shown at the top of FIG. 4-1, and a two-dimensional cross-section view 400-2 of the double-mode surface-acoustic-wave filter 124 is shown at the bottom of FIG. 4-1.

The double-mode surface-acoustic-wave filter 124 includes at least one electrode structure 302, at least one piezoelectric layer 304, and at least one substrate layer 306. In the depicted configuration shown in the two-dimensional cross-section view 400-2, the piezoelectric layer 304 is disposed between the electrode structure 302 and the substrate layer 306. A portion of the electrode structure 302 depicted in FIG. 4-1 includes at least a portion of one interdigital transducer 126 (IDT 126). The electrode structure 302 can include one or more additional interdigital transducers 126 not explicitly shown in FIG. 4-1. Also, the interdigital transducer 126 depicted in FIG. 4-1 can include additional fingers 312 not explicitly shown in FIG. 4-1.

In the three-dimensional perspective view 400-1, the interdigital transducer 126 is shown to have two comb-shaped structures 308-1 and 308-2 with fingers 312 extending towards each other from two busbars 310-1 and 310-2. As shown, the fingers 312 are arranged in an alternating or interlocking manner in between the two busbars 310-1 and 310-2 of the interdigital transducer 126 (e.g., arranged in an interdigitated manner). In other words, the fingers 312 connected to a first busbar 310-1 extend towards a second busbar 310-2 but do not connect to the second busbar 310-2. As such, there is a first barrier region 402-1 (e.g., a transversal gap region) between the ends of these fingers 312 of the first busbar 310-1 and the second busbar 310-2. Likewise, fingers 312 connected to the second busbar 310-2 extend towards the first busbar 310-1 but do not connect to the first busbar 310-1. There is therefore a second barrier region 402-2 between the ends of these fingers 312 from the second busbar 310-2 and the first busbar 310-1.

In a direction that can extend along a length of the busbars 310-1 and 310-2, there is an overlap region 404 that is based on an overlap between at least one pair of fingers 312. In the overlap region 404, a portion of one finger 312 overlaps with a portion of an adjacent finger 312 to define a width of the overlap region 404. In FIG. 4-1, by way of example only, two adjacent fingers extend from different busbars 310-1 and 310-2. This overlap region 404 may be referred to as an aperture, track, or active region where electric fields are produced between fingers 312 to cause an acoustic wave 406 to form or propagate in at least this region of the piezoelectric layer 304.

A physical periodicity of the fingers 312 is referred to as a pitch 414 of the interdigital transducer 126. The pitch 414 may be indicated or represented in various ways. For example, in certain aspects, the pitch 414 may correspond to a magnitude of a distance between adjacent fingers 312 of the interdigital transducer 126 in the overlap region 404. This distance may be defined, for example, as the distance between center points of each of the fingers 312. The distance may be generally measured between a right (or left) edge of one finger 312 and the right (or left) edge of an adjacent finger 312 when the fingers 312 have uniform widths. In certain aspects, an average of distances between adjacent fingers 312 of the interdigital transducer 126 may be used for the pitch 414 of a given section of the overlap region 404 along the first and second busbars 310-1 and 310-2. The frequency at which the piezoelectric layer 304 vibrates is a main-resonance frequency of the electrode structure 302. The frequency is determined at least in part by the pitch 414 of the interdigital transducer 126 in addition to other properties of the double-mode surface-acoustic-wave filter 124.

In the three-dimensional perspective view 400-1, the double-mode surface-acoustic-wave filter 124 is defined by a first (X) axis 408, a second (Y) axis 410, and a third (Z) axis 412. The first axis 408 and the second axis 410 are parallel to a planar surface of the piezoelectric layer 304, and the second axis 410 is perpendicular to the first axis 408. The third axis 412 is normal (e.g., substantially perpendicular or orthogonal) to the planar surface of the piezoelectric layer 304. The busbars 310-1 and 310-2 of the interdigital transducer 126 are oriented to be substantially parallel to the first axis 408. The fingers 312 of the interdigital transducer 126 are orientated to be substantially parallel to the second axis 410. Here, the term “substantially” connotes that the busbars or fingers are as parallel as a given manufacturing technology enables or connotes that the busbars or fingers are within 10%, 5%, or even 3% of being parallel. Also, an orientation of the piezoelectric layer 304 can cause the acoustic wave 406 to mainly form in a direction along or parallel to the first axis 408. As such, the acoustic wave 406 propagates in a direction that is substantially perpendicular or orthogonal to the direction of extension of the fingers 312 of the interdigital transducer 126.

FIG. 4-2 illustrates an example implementation of a double-mode surface-acoustic-wave filter 124 using a high-quality temperature-compensated surface-acoustic-wave (TC-SAW) filter stack that can have an apodized structure. A three-dimensional perspective view 400-3 of the double-mode surface-acoustic-wave filter 124 is shown at the top of FIG. 4-2, and a two-dimensional cross-section view 400-4 of the double-mode surface-acoustic-wave filter 124 is shown at the bottom of FIG. 4-2.

The double-mode surface-acoustic-wave filter 124 includes at least one electrode structure 302, at least one piezoelectric layer 304, and at least one compensation layer 326. The compensation layer 326 can provide temperature compensation to enable the double-mode surface-acoustic-wave filter 124 to achieve a target temperature coefficient of frequency. In example implementations, the compensation layer 326 can be implemented using at least one silicon dioxide layer.

In the depicted configuration shown in the two-dimensional cross-section view 400-4, the electrode structure 302 is disposed between the piezoelectric layer 304 and the compensation layer 326. The piezoelectric layer 304 can form a substrate of the double-mode surface-acoustic-wave filter 124 in at least some of such cases.

The electrode structure 302 of the high-quality temperature-compensated filter stack can be similar to the electrode structure 302 described above with respect to the thin-film surface-acoustic-wave filter stack of FIG. 4-1. Likewise, the piezoelectric layer 304 of the high-quality temperature-compensated filter stack can be similar to the piezoelectric layer 304 described above with respect to the thin-film surface-acoustic-wave filter stack of FIG. 4-1. The piezoelectric layer 304 of the high-quality temperature-compensated surface-acoustic-wave filter stack, however, can be thicker than the piezoelectric layer 304 of the thin-film surface-acoustic-wave filter stack of FIG. 4-1. Similar to the thin-film surface-acoustic-wave filter stack of FIG. 4-1, the high-quality temperature-compensated surface-acoustic-wave filter stack of FIG. 4-2 can also include the barrier regions 402-1 and 402-2 and the overlap region 404.

One of ordinary skill in the art can appreciate the variety of filter stacks in which the double-mode surface-acoustic-wave filter 124 can be implemented. It should be appreciated that although a certain quantity of fingers 312 are illustrated in FIGS. 4-1 and 4-2, the quantity of actual fingers, the lengths and widths of the fingers 312 and the busbars 310-1 and 310-2, the pitch of the fingers 312, and so forth may be different in a given physical implementation. Such parameters depend on the particular application and targeted filter characteristics. In addition, the double-mode surface-acoustic-wave filter 124 can include multiple interdigital transducers 126 to achieve a given filter transfer function. An example electrode structure 302 with multiple interdigital transducers 126 is described next with reference to FIG. 5.

FIG. 5 illustrates an example electrode structure 302 of a double-mode surface-acoustic-wave (DMS) filter 124 that can include apodization (not shown in FIG. 5). In the depicted configuration, the electrode structure 302 includes multiple interdigital transducers 126-1 to 126-N, where N represents a positive integer generally, to provide a DMS track. In example implementations, the variable N can be equal to 3, 4, 5, 7, and so forth. Thus, a DMS track can include an arbitrary number of interdigital transducers. With reference also to FIG. 2, a receive filter (e.g., the DMS filter 124) or a transmit filter 240 can include at least one DMS track.

The electrode structure 302 also includes a first reflector 314-1 and a second reflector 314-2. The interdigital transducers 126-1 to 126-N are arranged between the first and second reflectors 314-1 and 314-2. The interdigital transducers 126-1 to 126-N can be, for instance, arranged so as to be spatially or physically positioned sequentially or in series together between the first and second reflectors 314-1 and 314-2. With this positioning, the reflectors 314-1 and 314-2 reflect the acoustic wave 406 (of FIGS. 4-1 and 4-2) back towards the interdigital transducers 126-1 to 126-N. Each reflector 314-1 and 314-2 within the electrode structure 302 can have two busbars 310 and a grating structure of conductive finger-like strips that connect to both busbars 310. In some implementations, a pitch of the reflector 314 can be similar to a pitch 414 of an interdigital transducer 126 to reflect the acoustic wave 406 in the resonant frequency range.

As shown, each interdigital transducer 126 includes a first busbar 310-1, a second busbar 310-2, and multiple fingers 312-1 to 312-B, where B represents a positive integer. The first busbar 310-1 and the fingers 312-1 to 312-A form at least a portion of the first comb-shaped structure 308-1, where A represents a positive integer that is less than B. The fingers 312-1 to 312-A are connected to the first busbar 310-1 and extend along the second (Y) axis 410 towards the second busbar 310-2 without connecting to the second busbar 310-2. The second busbar 310-2 and the fingers 312-(A+1) to 312-B form at least a portion of the second comb-shaped structure 308-2. The fingers 312-(A+1) to 312-B are connected to the second busbar 310-2 and extend along the second (Y) axis 410 towards the first busbar 310-1 without connecting to the first busbar 310-1.

The fingers 312 within an interdigital transducer 126 can be associated with, for example, a first transition region 128-1, a central region 502, or a second transition region 128-2. In the depicted example, the central region 502 is positioned between the first and second transition regions 128-1 and 128-2 along the first axis 408. The first and second transition regions 128-1 and 128-2 are associated with opposite outer edges of the interdigital transducer 126. For instance, the first transition region 128-1 is associated with a “left” edge (as depicted in FIG. 5) of the interdigital transducer 126, and the second transition region 128-2 is associated with a “right” edge of the interdigital transducer 126.

Although not explicitly shown in FIG. 5, the first and second transition regions 128-1 and 128-2 can also include fingers 312 of a respective “left” and “right” adjacent interdigital transducer 126. In some cases, a transition region 128 can include 30%, 20%, 10%, or even 5% of the fingers or spatial length of each interdigital transducer 126 of the two interdigital transducers 126 over which the transition region 128 extends. The remainder of each interdigital transducer 126 can correspond to another transition region 128 and the central region 502, another one or more regions, a combination thereof, and so forth. The central region 502 is associated with a center of the interdigital transducer 126 and does not include additional fingers 312 associated with an adjacent interdigital transducer 126. In some cases, a central region 502 can include 60%, 40%, 20%, or even 10% of the fingers or spatial length of a given interdigital transducer 126. The remainder of the given interdigital transducer 126 can correspond to first and second transition regions 128-1 and 128-2, another one or more regions, a combination thereof, and so forth. In other implementations, an interdigital transducer 126 can include more, fewer, and/or different regions as compared to those shown in FIG. 5. For example, an interdigital transducer 126 can include a transition region 128 that is not positioned at or otherwise associated with an edge of the interdigital transducer 126.

A transition region 128 can facilitate a smoother, less abrupt change along the track for the acoustic wave with respect to sets of fingers that exhibit different apodization properties 130. At least one transition region 128 can include, for instance, portions of two adjacent interdigital transducers 126 that jointly suppress one or more spurious modes, including at least one 2D spurious mode. Additionally or alternatively, at least one transition region 128 can include finger portions that support a respective apodization property 130 in a respective interdigital transducer 126 (e.g., that support a respective phase shift 134 of the respective interdigital transducer 126 for the apodization of the DMS filter 124). Generally, a region, such as a transition region 128 or a central region 502, can include different apodization properties 130 relative to those of one or more other regions, including within a same interdigital transducer 126 or with respect to or within a different interdigital transducer 126. For example, a period 132, a phase 134, an amplitude 136, a curvilinear characteristic 138, or a slope 140 of the fingertips, piston mode structures, an aperture, or a combination thereof of one or more interdigital transducers 126 can vary across the first axis 408 and the second axis 410 in a 2D manner, as is further described herein. Next, however, an example DMS filter 124, including example circuit couplings, is described with reference to FIG. 6.

FIG. 6 illustrates an example double-mode surface-acoustic-wave filter 124 having at least one transition region 128 that can relate to at least one apodization property 130 (not shown in FIG. 6). The double-mode surface-acoustic-wave filter 124 includes at least one input port 602 and at least one output port 604. In this example, the double-mode surface-acoustic-wave filter 124 includes seven interdigital transducers 126 (e.g., interdigital transducers 126-1, 126-2, 126-3, 126-4, 126-5, 126-6, and 126-7). Other implementations are also possible in which the double-mode surface-acoustic-wave filter 124 includes two, three, four, five, six, or more interdigital transducers 126.

In general, at least two of the interdigital transducers 126 have first busbars 310-1 (e.g., of FIGS. 3 to 5) coupled to the input port 602 and second busbars 310-2 coupled to a ground 606. At least one of the interdigital transducers 126 has a first busbar 310-1 coupled to the output port 604 and a second busbar 310-2 coupled to the ground 606. The at least one interdigital transducer 126 that is coupled to the output port 604 is interspersed between the at least two interdigital transducers 126 coupled to the input port 602. Generally, those interdigital transducer(s) 126 that are coupled between the output port 604 and the ground 606 are disposed in an alternating sequence along the DMS track with those interdigital transducer(s) 126 that are coupled between the input port 602 and the ground 604.

In this example, four interdigital transducers 126 (e.g., interdigital transducers 126-1, 126-3, 126-5, and 126-7) have first busbars 310-1 coupled to the input port 602 and second busbars 310-2 coupled to the ground 606 (or vice versa). Three interdigital transducers 126 (e.g., interdigital transducers 126-2, 126-4, and 126-6) are interspersed between the four odd-numbered interdigital transducers 126. The three even-numbered interdigital transducers 126 have first busbars 310-1 coupled to the output port 604 and second busbars 310-2 coupled to the ground 606 (or vice versa). However, the principles that are described herein, including apodization techniques, are applicable in other filter implementations. For example, one or more interdigital transducers 126 may have different connection(s) to each other or to other circuit components. Also, an individual resonator may be coupled to a port or be free floating instead of being coupled to the ground, or a ladder structure may be coupled along a signal flow of components before the input port 602. Other example implementations may also employ the techniques described herein.

As shown in FIG. 6, the double-mode surface-acoustic-wave filter 124 includes multiple transition regions 128 (e.g., six transition regions 128-1, 128-2, 128-3, 128-4, 128-5, and 128-6 between the seven interdigital transducers 126). These transition regions 128 or other region(s), for example, can include fingertips, piston mode structures, an aperture, or a combination thereof, that realize at least one apodization property 130 as described herein, including with reference to FIG. 8 and succeeding figures. Next, however, example implementations of piston mode structures are described in the context of at least one interdigital transducer 126 and a DMS filter 124 with reference to FIGS. 7-1 and 7-2.

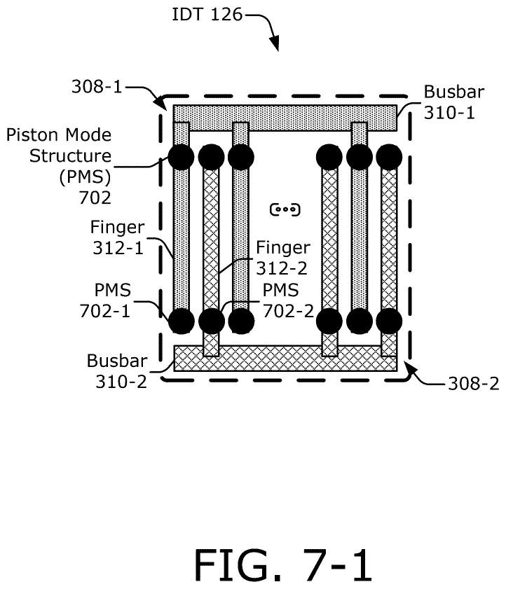

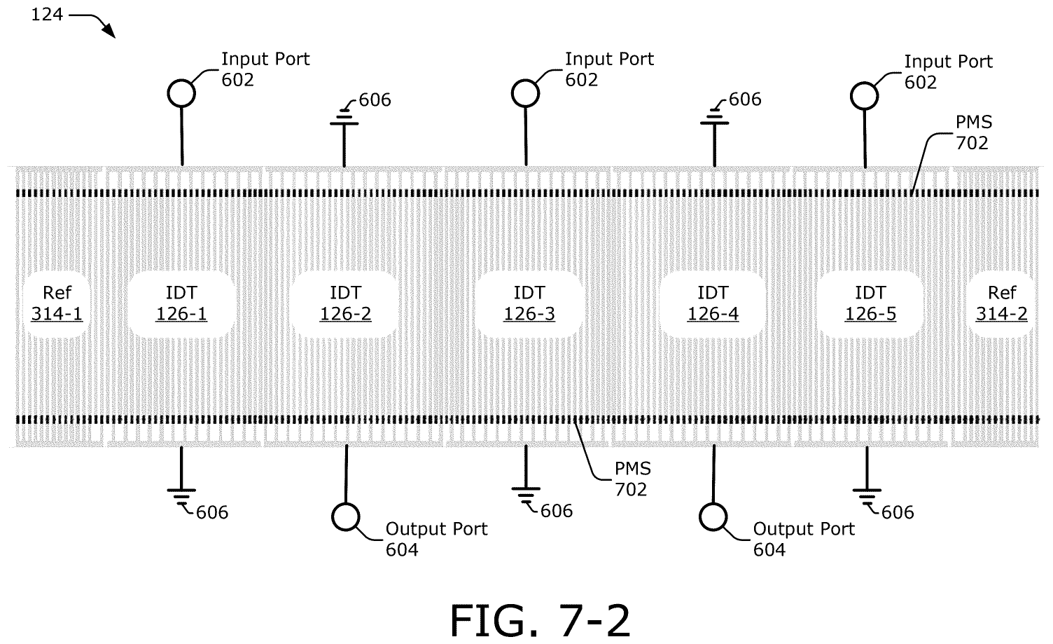

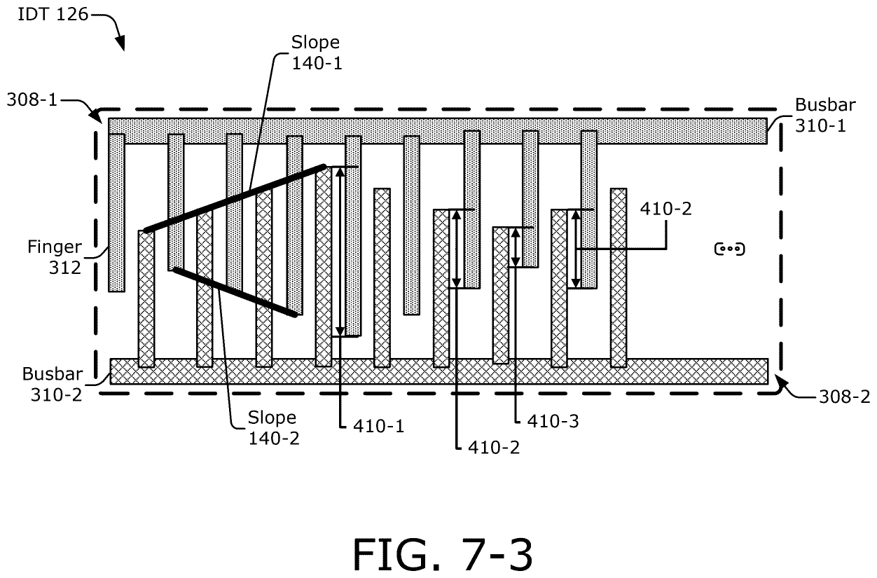

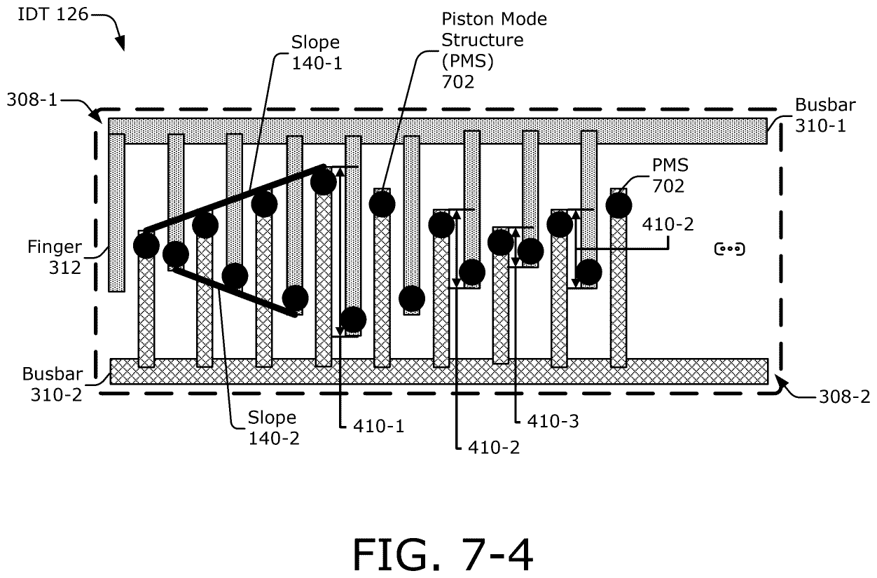

FIG. 7-1 illustrates an example of multiple piston mode structures 702 of an interdigital transducer 126, which may be part of a double-mode surface-acoustic-wave filter 124 (not depicted in FIG. 7-1). As shown, each finger 312 can include at least one piston mode structure 702. In example implementations, a piston mode structure can shape a form of a piston mode of a double-mode surface-acoustic-wave filter 124 or an interdigital transducer 126 thereof. For instance, ends of fingers can be altered to lower a velocity of a propagating wave (e.g., in a trap region of the filter). Piston-mode structures can change the velocity profile in the transversal direction of the double-mode surface-acoustic-wave filter 124.

By way of example, a piston mode structure 702 can correspond to a portion of a finger 312 having a different structure, such as a different mass or shape (including having a different mass and a different shape in some cases), as compared to the majority of the finger 312. For example, a piston mode structure 702 can have an increased mass (e.g., by being fabricated with a greater height or width or with a deposit of a heavier material as compared to most of the finger 312). Or a piston-mode structure 702 can have a decreased mass (e.g., by being fabricated with a lesser height or width as compared to most of the finger 312 or with a lower weighted material).

For other examples, a shape of each piston mode structure 702 can differ from the majority (e.g., more than half) of the remainder of the finger 312. For example, the piston mode structure 702 may occupy a smaller area or a greater area. Further, the piston mode structure 702 may flare out or include a cutaway segment relative to the majority of the finger, may have a circular or rectangular shape, may have an arrowhead or shovel-head shape, may be a hammerhead at the fingertips, some combination thereof, and so forth.

Additionally or alternatively, a piston-mode structure 702 can be realized with one or more silicon dioxide (SiO2) stripes or with a change to the piezoelectric material below the fingers near the distal ends of the fingers (e.g., near the fingertips). In other implementations, piston-mode structures 702 can be formed using longitudinal dielectric bars disposed over the ends of the fingers. Further, any of the described approaches or other approaches to creating piston-mode structures 702 can be combined in a given implementation. For clarity, piston mode structures 702 are depicted in the drawings as solid dark circles or rectangles; however, piston mode structures 702 may have different shapes or sizes or may be constructed differently as described herein.

As shown, a piston mode structure 702-1 may be positioned at or near a distal tip of a finger 312-1 (e.g., where a finger 312 terminates without contacting the opposite busbar 310). The piston mode structure 702 may terminate a finger 312, or some portion of the “regular” shape and mass of the finger 312 may extend slightly beyond the piston mode structure 702. Thus, in some implementations, each finger 312 includes or otherwise corresponds to a respective piston mode structure 702 positioned at least proximate to at a distal tip of the respective finger 312. In some cases, each finger may also or instead include a respective piston mode structure 702 that is positioned nearer a proximal end of the respective finger 312 (e.g., where a finger 312 originates or contacts a busbar 310). An example of this positioning is shown with a piston mode structure 702-2 of a finger 312-2. It is noted that the reference numbers of individual fingers 312-x differ among the various figures for simplicity, such as between FIG. 7-1 and FIG. 5.

As shown in FIG. 7-1, the piston mode structure 702-2 positioned near the proximal end (or origin) of the finger 312-2 may correspond to the piston mode structure 702-1 of the finger 312-1, which is adjacent to the finger 312-2. Here, a correspondence may relate to the second piston mode structure 702-2 being positioned along the second finger 312-2 in substantial alignment with the first piston mode structure 702-1 of the first finger 312-1, which can jointly form part of an apodized structure (not explicitly denoted in FIG. 7-1). The first piston mode structure 702-1 and the second piston mode structure 702-2 may also be substantially equidistant from the second busbar 310-2, but optionally not exactly equidistant so as to enable piston mode structures 702 to comport with an apodization structure as described herein.

In accordance with described techniques, the piston mode structures 702 can be positioned on the fingers 312 of an interdigital transducer 126 based on an apodization of the double-mode surface-acoustic-wave filter 124, on an overall apodization schema of the double-mode surface-acoustic-wave filter 124, on at least one apodization property 130 of the interdigital transducer 126, some combination thereof, and so forth. From an alternative perspective, the alignment between two or more piston mode structures 702 can realize or define an apodization of a double-mode surface-acoustic-wave filter 124 or an apodization property 130 thereof. As also described herein, the apodization of a double-mode surface-acoustic-wave filter 124 or an apodization property 130 thereof can be realized or defined separate or independently of one or more piston mode structures 702. The apodization of a double-mode surface-acoustic-wave filter 124 or an apodization property 130 thereof can be realized or defined based on the lengths of fingers or the length of overlap of neighboring fingers along a width of the double-mode surface-acoustic-wave filter 124, including being based on both finger length and overlap length. Further, an apodization of a double-mode surface-acoustic-wave filter 124 or an apodization property 130 thereof can be formed with one or more interdigital transducers having fingers that omit or lack piston mode structures 702.

Other figures depict piston mode structures without apodization or with an apodization structure. Each of FIGS. 8 through 10 depicts at least a portion of a double-mode surface-acoustic-wave filter 124 having piston mode structures 702 that are placed in accordance with an example apodization schema. FIGS. 8 through 10 can, however, illustrate an apodization schema without any piston mode structures 702 based on an aperture of the double-mode surface-acoustic-wave filter 124 or an interdigital transducer 126 thereof. In contrast with FIGS. 8 through 10, FIG. 7-2 depicts a double-mode surface-acoustic-wave filter 124 having piston mode structures 702 that are not placed in accordance with an apodization.

FIG. 7-2 illustrates an example double-mode surface-acoustic-wave filter 124 that has piston mode structures 702 but lacks apodization. As depicted, the double-mode surface-acoustic-wave filter 124 includes five interdigital transducers 126-1 to 126-5 and two reflectors 314-1 and 314-2. The piston mode structures 702 are depicted as black rectangles. Each finger 312 includes a pair of piston mode structures 702: one piston mode structure 702 near the distal tip or termination of the finger 312 and another piston mode structure 702 near the proximal portion or origin of the finger 312. In FIG. 7, the double-mode surface-acoustic-wave filter 124 lacks apodization. The aperture, or overlap region, is constant in terms of width and position along the length of the double-mode surface-acoustic-wave filter 124. Accordingly, the fingers have a common length, and the piston mode structures 702 are a constant distance from the busbars in this example.

Thus, in FIG. 7-2, the aperture, or overlap region 404 (of FIGS. 4-1 and 4-2) that occupies part of the width of the double-mode surface-acoustic-wave filter 124, is constant across the DMS track that extends along the length of the double-mode surface-acoustic-wave filter 124. In contrast with FIG. 7-2, FIGS. 7-3 and 7-4 depict part of a double-mode surface-acoustic-wave filter 124 that has overlap regions 404 of different widths to produce a varying aperture to establish an apodization. FIG. 7-3 omits piston mode structures, but FIG. 7-4 includes piston mode structures 702.

FIG. 7-3 illustrates an example interdigital transducer 126 having apodization that is realized with varied lengths of an overlap of neighboring fingers 312. The interdigital transducer 126 may be part of a double-mode surface-acoustic-wave filter 124. As shown, three different overlap regions are explicitly indicated with three different widths. A first overlap region 410-1 has a first width, which is the widest indicated overlap region 410 in FIG. 7-3. A second overlap region 410-2 has a second width that is less than that of the first overlap region 410-1. A third overlap region 410-3 has a third width that is shorter than the second width. The widths of each of these overlap regions 410 correspond to the overlap lengths between at least two fingers, such as two adjacent fingers.

The different widths of these overlap regions 410 can therefore establish a spatially varying aperture of the interdigital transducer 126 (or a spatially varying aperture of a double-mode surface-acoustic-wave filter 124 that includes the depicted interdigital transducer 126). This spatially varying aperture realizes an apodization structure for the interdigital transducer 126. Examples of aperture structures 802 with apodization are depicted more clearly in FIGS. 8 through 11-3 (e.g., as also reflected in FIG. 8 as an aperture 804). In FIG. 7-3, two slopes of an aperture are indicated: a first slope 140-1 and a second slope 140-2. In this example, the second slope 140-2 is the negative of the first slope 140-1 (e.g., the two slopes have the same absolute value but opposite signs).

FIG. 7-4 illustrates an example interdigital transducer 126 having apodization that is realized with varied lengths of an overlap of neighboring fingers. In contrast with FIG. 7-3, however, each finger 312 includes at least one piston mode structure 702. It should be noted that the piston mode structures 702 of the various figures are not necessarily depicted to scale. In FIG. 7-4, each finger 312 includes a piston mode structure 702 near the distal end or termination of the finger 312. Each finger 312 omits or lacks another piston mode structure 702 near the proximal end or origin of the finger 312. However, each finger 312 may also include at least one piston mode structure 702 at each end of one or more fingers 312. For example, FIGS. 7-2 and 8 have two piston mode structures 702 per finger 312. Further, in other implementations, one or more fingers 312 may include a piston mode structure 702 near the proximal end or origin of the finger 312 (e.g., the end nearer the busbar 310) while omitting one at the distal end or termination of the finger 312.

FIGS. 8 through 10 include piston mode structures 702 at the distal end and near the proximal end of each finger 312 for visual clarity. This enables the apodization schema to be seen more clearly in the drawings. However, any of the depicted examples may be implemented by omitting one or two (e.g., including both) piston mode structures 702 from one or more fingers 312, including up to all fingers 312 of a double-mode surface-acoustic-wave filter 124. Thus, an apodization schema or structure of a double-mode surface-acoustic-wave filter 124 can be established based on an overlap between two or more fingers 312, such as between two adjacent fingers 312. The overlap length (or width of an overlap region 410 having a length parallel to the length of a double-mode surface-acoustic-wave filter 124) can define or determine an aperture of the double-mode surface-acoustic-wave filter 124. An example aperture is described next with reference to FIG. 8 and in conjunction with other apodization properties 130.

FIG. 8 illustrates an example double-mode surface-acoustic-wave filter 124 with piston mode structures 702 that exhibit or comport with an example apodized structure 802 that is established by varying lengths of finger overlap. As depicted, the double-mode surface-acoustic-wave filter 124 includes five interdigital transducers 126-1 to 126-5 and two reflectors 314-1 and 314-2. The piston mode structures 702 are depicted as rectangles. Each finger 312 includes a pair of piston mode structures 702: one piston mode structure 702 at the distal tip of the finger 312 and another piston mode structure 702 near the proximal portion or origin of the finger 312. In this example, the double-mode surface-acoustic-wave filter 124 has an apodization schema that is based on a trigonometric function. Accordingly, the apodized structure 802, including a first part of the apodized structure 802-1 that is nearer the input port 602 and a second part of the apodized structure 802-2 that is nearer the output port 604, is depicted as at least one sine or cosine wave.

In example implementations, an apodization schema or apodized structure 802 of a DMS filter 124 can include one or more apodization properties 130 (e.g., of FIGS. 1 and 3). A period 132 is shown relative to a length of one or more IDTs 126. In the example of FIG. 8, the indicated period 132 extends across the second IDT 126-2 and the third IDT 126-3. Thus, in this example, there is one-half (½) period 132 of the apodized structure 802 per IDT 126. A phase shift 134 is shown at the border between the first and second IDTs 126-1 and 126-2 at a transition region 128-1. Additional examples of periods 132 and phase shifts 134 are described below with reference to FIGS. 9-1 to 9-4. An amplitude 136 can be a distance from a peak to the midpoint or from the midpoint to a trough (e.g., or half the peak-to-peak distance) of the apodized structure 802.

An aperture 804, which can correspond to a spatially varying overlap region 404 (e.g., of FIGS. 4-1 and 4-2) or to multiple overlap regions 410-1 to 410-3 with different widths (e.g., of FIGS. 7-3 and 7-4) is also indicated. The aperture 804 is defined as a distance between distal tips of the fingers 312. With piston mode structures 702 disposed at least proximate to the distal tips of fingers 312 that extend from the two busbars, the aperture 804 can also represent or correspond to the average distance between piston mode structures 702 that are proximate to opposite busbars (e.g., along a single finger 312 with two piston mode structures 702 per finger). As shown, the aperture 804 varies over the DMS track due to the impact of the trigonometric function on the lengths of fingers (e.g., as indicated by the positioning of the piston mode structures 702) and the reflective relationship between the first and second parts of the apodized structure 802-1 and 802-2.

Additional examples of apodization schema for a double-mode surface-acoustic-wave filter 124 are described next with reference to FIGS. 9-1 to 9-4. In these figures, the electrical coupling points (e.g., the input port 602, the output port 604, and the ground 606) have been omitted for clarity.

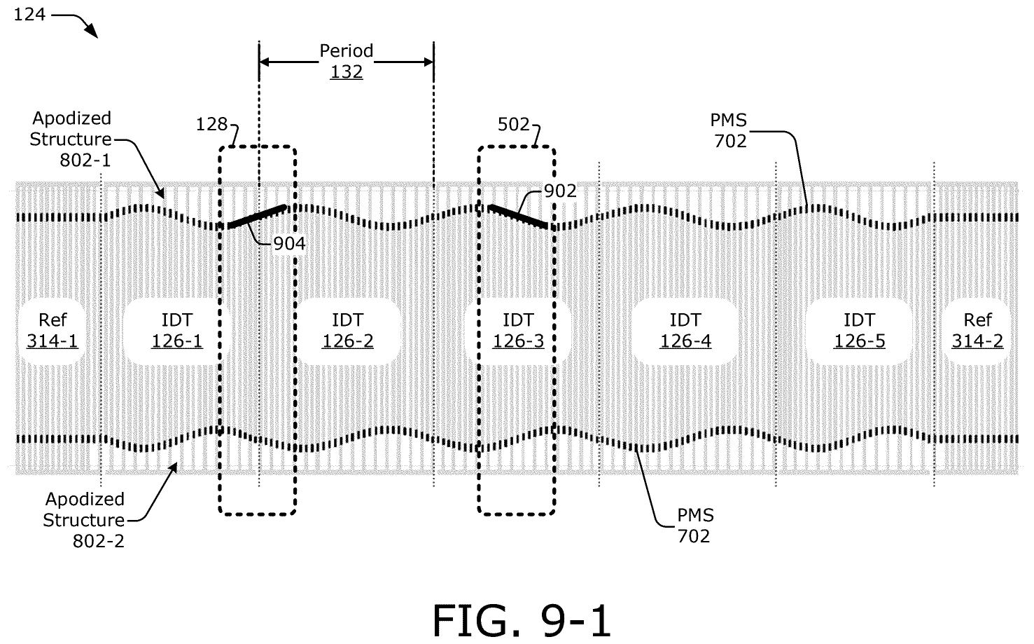

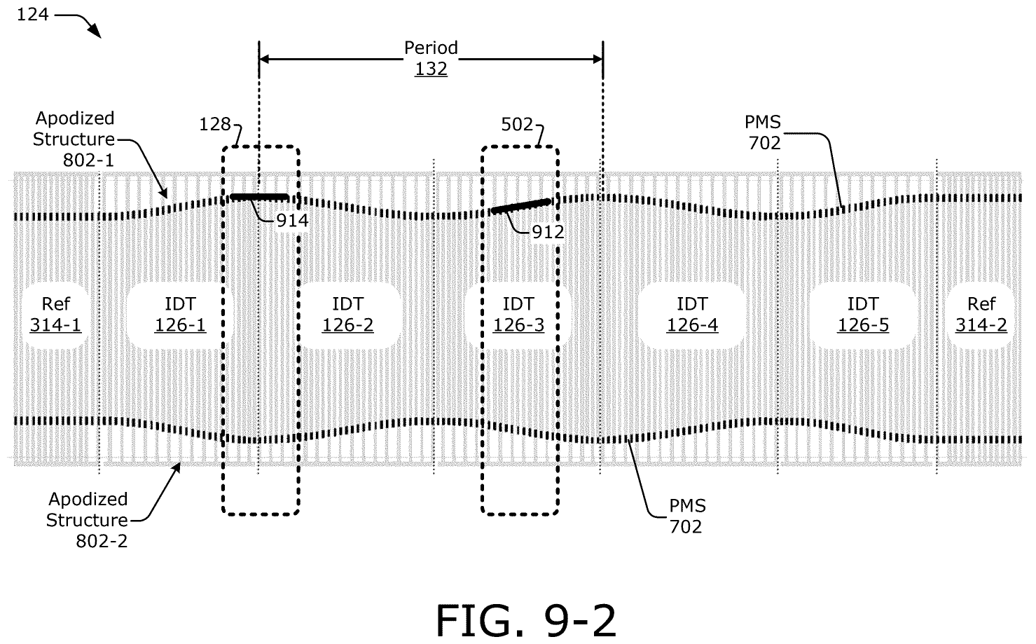

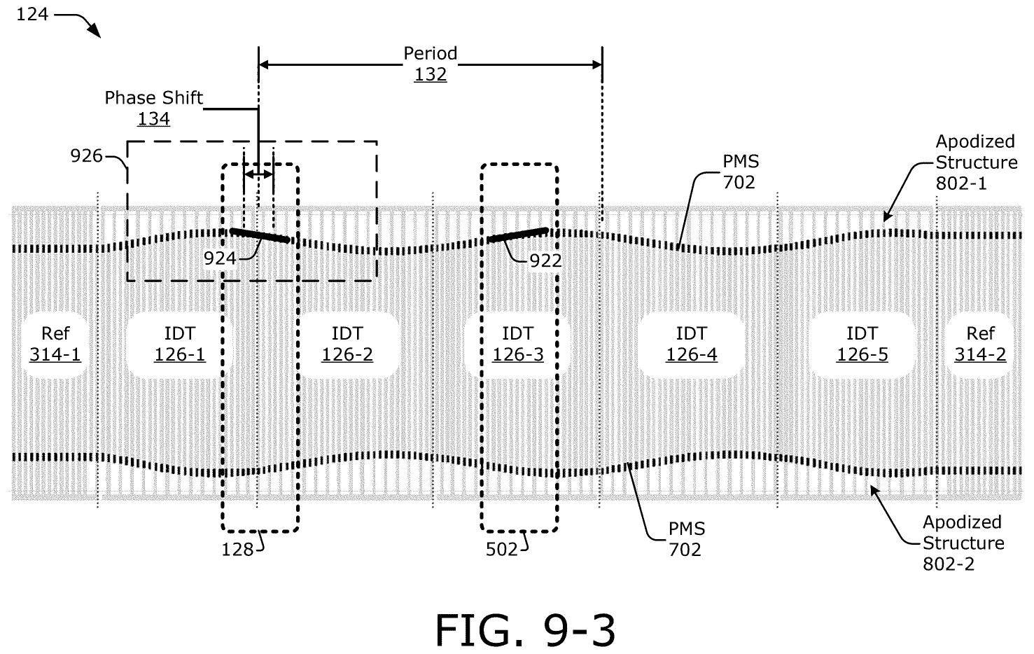

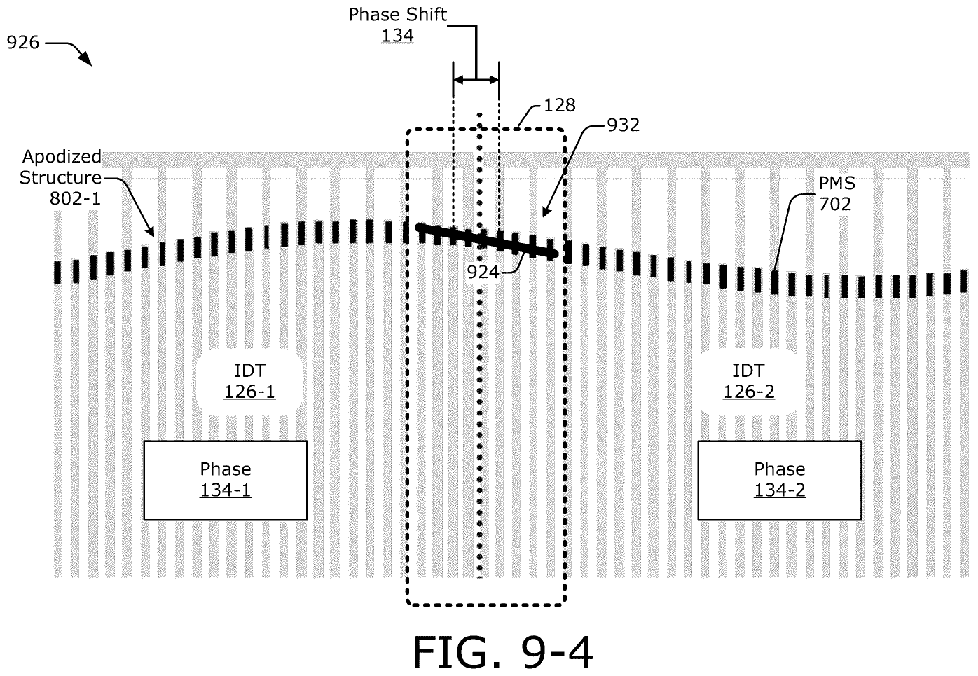

FIGS. 9-1, 9-2, and 9-3 illustrate examples of double-mode surface-acoustic-wave filters 124 with different example apodized structures 802. Each of these example apodized structures 802 is based on trigonometric apodizations (e.g., sine or cosine waves). In FIG. 9-1, the apodized structure 802 has one (sine) period 132 per interdigital transducer 126. The portions of this apodized structure 802 having a maximum slope 902 are aligned in the central region 502 (one of which is explicitly indicated) of each interdigital transducer 126. The portions of the apodized structure 802 in each transition region 128 (one of which is explicitly indicated) also have a relatively steep slope 904.

In FIG. 9-2, the apodized structure 802 has one-half (cosine) period 132 per interdigital transducer 126. The portions of this apodized structure 802 having a maximum slope 912 are again aligned in the central region 502 of each interdigital transducer 126. In contrast with FIG. 9-1, however, the portions of the apodized structure 802 in each transition region 128 have a vanishing slope 914 that approaches or equals zero degrees (0°). The vanishing slope 914 at the transition region 128 can contribute to spurious modes arising from the trap region of the double-mode surface-acoustic-wave filter 124.

In FIG. 9-3, like in FIG. 9-2, the apodized structure 802 has a one-half (cosine) period 132 per interdigital transducer 126. The portions of this apodized structure 802 having a maximum slope 922 are still aligned in the central region 502 of each interdigital transducer 126. In contrast with FIG. 9-2, however, by implementing a per-IDT apodization schema, the resulting apodized structure 802 has a non-vanishing slope 924 in each transition region 128 (one of which is explicitly indicated). In this example, to create the non-vanishing slope 924 in the transition region 128, a phase shift 134 is created in the apodized structure 802 between the first and second interdigital transducers 126-1 and 126-2. A size of the phase shift 134 can be between, for instance, one degree and ninety degrees (1° and 90°). An area 926 is demarcated in FIG. 9-3 with a rectangle having long-dashed lines. An expanded, zoomed-in depiction of the area 926 is illustrated in FIG. 9-4 to better demonstrate the phase shift 134 along the apodized structure 802.

FIG. 9-4 depicts an enlarged view of a portion of the example double-mode surface-acoustic-wave filter 124 of FIG. 9-3 to illustrate an example phase shift 134 between two adjacent interdigital transducers. As shown, the area 926 (also of FIG. 9-3) includes sections of the first and second interdigital transducers 126-1 and 126-2. In example implementations, a transition region 128 is overlaying a border between the first interdigital transducer 126-1 and the second interdigital transducer 126-2. The transition region 128 includes a transition portion 932 of the apodized structure 802, such as the portion of the apodized structure 802 that is within the transition region 128. The transition portion 932 has a non-vanishing slope 924. Generally, a non-vanishing slope can include a slope that is greater than 3°, greater than 5°, greater than 10°, or even greater than 20°.

The non-vanishing slope 924 can be created by tuning any of the apodization properties 130 (e.g., of FIGS. 1 and 3) that are described herein. In the example of FIGS. 9-3 and 9-4, however, the non-vanishing slope 924 is created by the phase shift 134, which is based on a first phase 134-1 and a second phase 134-2. A first portion of the apodized structure 802-1 that corresponds to the first interdigital transducer 126-1 exhibits or has the first phase 134-1. A second portion of the apodized structure 802-1 that corresponds to the second interdigital transducer 126-2 exhibits or has the second phase 134-2. A difference between the first phase 134-1 and the second phase 134-2 establishes the phase shift 134 between the two portions of the apodized structure 802-1.

The phase shift 134 can be established in either direction. From a geometric point of view, an appropriate phase shift amount may depend on the number of fingers in each interdigital transducer 126 and on the pitch profile in the transition region 128. From a functional point of view, acoustic modes in the DMS track can be simulated. Based on the simulations, the phase shift 134 can be adjusted so that it is relatively larger in the region(s) where the spurious modes are located and relatively smaller (including zero) in the other region(s). This enables a distinct reduction of the spurious modes without inducing too much additional loss on the other, desirable acoustic modes. Thus, for attaining a suitable compromise between insertion loss (e.g., electrical performance) and spurious modes reduction, the phase shift 134 is one of the apodization properties 130 that can be adjusted. For instance, the cavity mode in a DMS is localized in the transition region of the DMS. The cavity mode is spuriously affected by the non-vanishing slope in the transition between interdigital transducers 126, and the spurious mode can be suppressed by adjusting the phase.

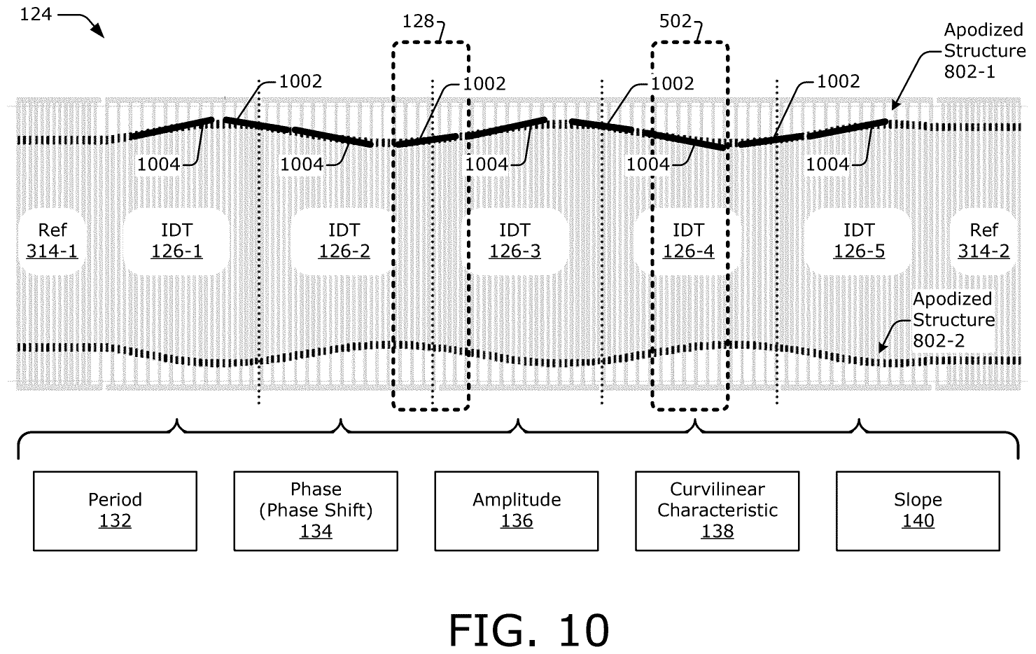

The phase or phase shift 134 apodization property can represent the alignment or misalignment of the maxima/minima of the apodization function with respect to the center of the transition region 128. As depicted, the apodized structure 802-1 can be continuous across the transition region 128, even with the phase shift 134. The overall apodization can be maintained by the apodized structure 802-1 by tuning any of the apodization properties 130 at each individual interdigital transducer 126. Examples of this approach are described next with reference to FIG. 10.

FIG. 10 illustrates an example double-mode surface-acoustic-wave filter 124 having an example apodized structure 802 in which the slope 140 is non-vanishing in one or more regions. In example implementations, the slope 140 of the apodized structure 802 is established to be non-vanishing at each transition region 128 between two interdigital transducers 126 and at each central region 502 of each interdigital transducer 126. Each transition region 128 has a non-vanishing slope 1002, and each central region 502 has a non-vanishing slope 1004.

For clarity, only one transition region 128 of the four transition regions and only one central region 502 of the five central regions are explicitly indicated in FIG. 10. Further, fewer than all included regions may have a corresponding slope 140 that is adjusted to be non-vanishing in some cases. Additionally, a double-mode surface-acoustic-wave filter 124 may include more or fewer than five interdigital transducers 126.

In example techniques to create an apodized structure 802 that reduces spurious modes, any of the noted apodization properties 130 or other properties may be adjusted or tuned. These properties include a period 132, a phase shift 134, an amplitude 136, a curvilinear characteristic 138, a slope 140, combinations thereof, and so forth. One or more of these apodization properties 130 can be adjusted jointly or individually for each interdigital transducer 126 and up to all interdigital transducers 126 of a given double-mode surface-acoustic-wave filter 124. Thus, the apodization function of the apodized structure 802 across the double-mode surface-acoustic-wave filter 124 can be defined in a piecewise fashion, such as in a per-IDT manner.

By using a piecewise-defined apodization function, the shape of the apodization (e.g., amplitude and number of maxima/minima) can be adjusted for each interdigital transducer 126 individually. Similarly, the phase shift 134 can be adjusted individually for each transition region 128 overlaying a border between two interdigital transducers 126. The phase shift 134 can therefore be enhanced (e.g., adjusted to reduce spurious modes or optimized) according to the geometry. For instance, the phase shift 134 may be based on a number of chirped fingers in the transition region 128. In particular, the phase shift 134 may be different for each transition region 128, depending on the result of the enhancement process. In some cases, the piecewise-defined apodization function can be selected or tuned such that the function is continuous across the double-mode surface-acoustic-wave filter 124, including in the transition regions 128. By making the apodized structure 802 continuous, acoustic loss and excitation of additional spurious modes can be avoided at the outer regions of the track (e.g., in the trap regions near the busbars).

Generally, the excitation of spurious modes is observed in both regular and transitions regions, absent implementation of the techniques described herein. The continuity of the apodized structure 802 between two adjacent interdigital transducers 126 (and across the “whole” double-mode surface-acoustic-wave filter 124) can be preserved by the ability to define the apodization function for each individual interdigital transducer 126. With respect to the phase shift 134 apodization property 130, the phase parameters of two adjacent interdigital transducers 126 can be adjusted to ensure the continuity of the overall apodization function. This tuning of one or more apodization properties 130 can produce a non-vanishing slope in the regions where the spurious modes would otherwise be located, such as at the transition regions 128 and the central regions 502.

FIGS. 11-1, 11-2, and 11-3 illustrate examples of double-mode surface-acoustic-wave filters 124-1 to 124-5 with additional example apodizations, including with different example curvilinear characteristics 138 (e.g., of FIGS. 1, 3, and 10). As shown, each double-mode surface-acoustic-wave filter 124 includes three interdigital transducers 126-1 to 126-3 and two reflectors 314-1 and 314-2. Nonetheless, the principles that are described with reference to FIGS. 11-1 to 11-3 are applicable to double-mode surface-acoustic-wave filters 124 with different quantities of interdigital transducers or reflectors. As illustrated, the first interdigital transducer 126-1 is longer than the second interdigital transducer 126-2, and the third interdigital transducer 126-3 is longer than the first interdigital transducer 126-1. The relative lengths of the interdigital transducers 126 can, however, be different, including by having two or more interdigital transducers 126 with equal lengths. Similarly, the relative lengths of the interdigital transducers 126 of, e.g., FIGS. 8 through 10 can be different from the illustrated lengths.

Each double-mode surface-acoustic-wave filter 124 includes an apodized structure 802. The apodized structure 802 may include a first part of the apodized structure 802-1 and a second part of the apodized structure 802-2. The illustrated apodized structures 802 in FIGS. 11-1 to 11-3 may correspond to an overlap region of fingers (e.g., an overlap between two adjacent fingers) along a length of a double-mode surface-acoustic-wave filter 124. Thus, the depicted lines of the apodized structures 802 can correspond to distal tips of fingers of interdigital transducers, piston mode structures disposed on fingers of the interdigital transducers, some combination thereof, and so forth. The different apodized structures 802 illustrate just a few examples of different curvilinear characteristics 138 (e.g., of FIGS. 1, 3, and 10) that can be applied to double-mode surface-acoustic-wave filters 124 besides the ones illustrated in earlier figures.

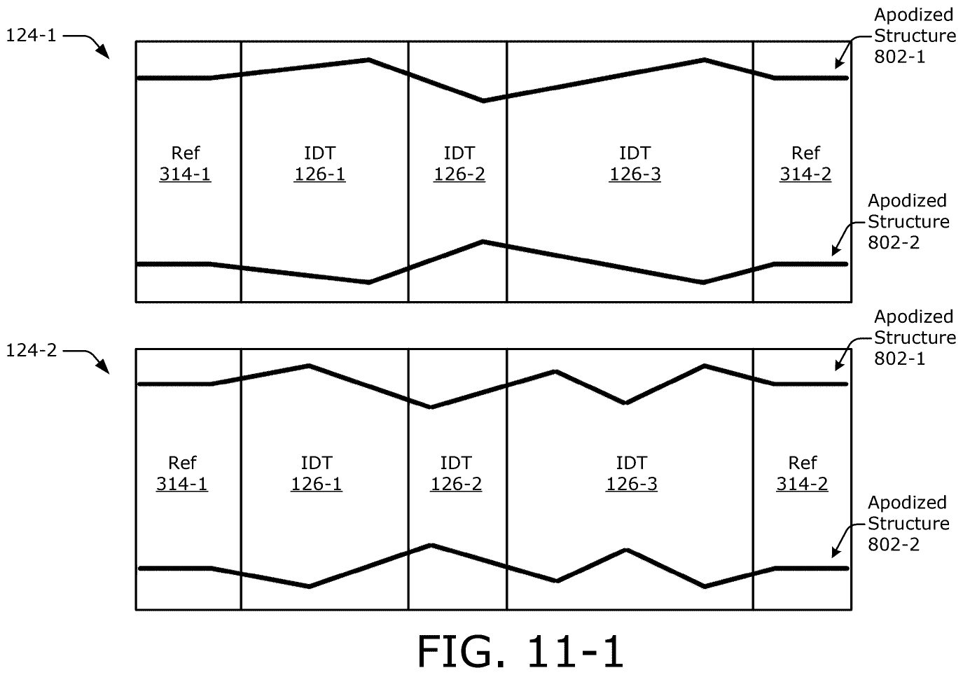

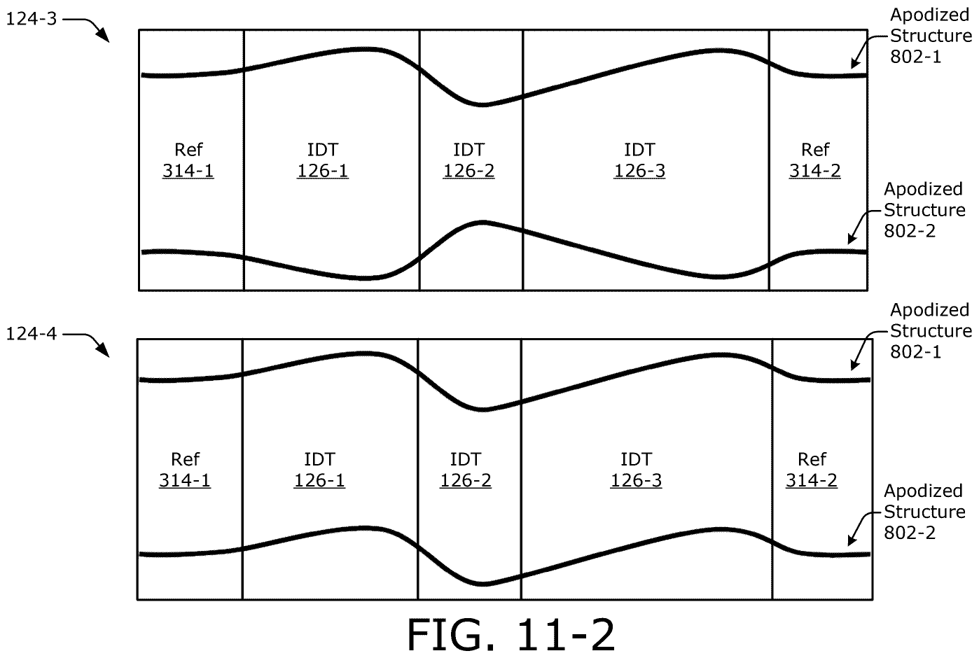

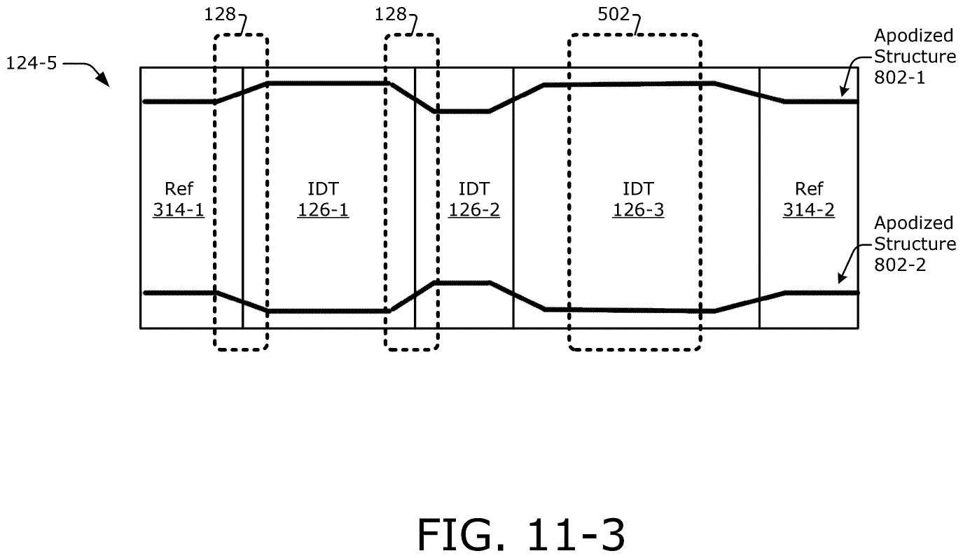

With reference to FIG. 11-1, in example implementations, the double-mode surface-acoustic-wave filters 124-1 and 124-2 have example piecewise linear apodization functions. In the double-mode surface-acoustic-wave filter 124-1, the apodized structure 802 has one maxima/minima (or extrema) per interdigital transducer 126. In contrast, each interdigital transducer 126 in the double-mode surface-acoustic-wave filter 124-2 can have multiple maxima/minima per interdigital transducer 126. For example, the third, and longest, interdigital transducer 126-3 in the double-mode surface-acoustic-wave filter 124-2 has three maxima/minima (or three extrema).

With reference to FIG. 11-2, in example implementations, the double-mode surface-acoustic-wave filters 124-3 and 124-4 have example irregular apodization functions, which may still be differentiable. These structures can be parallel (e.g., substantially identical) to each other. In the double-mode surface-acoustic-wave filter 124-3, the two parts of the apodized structure 802-1 and 802-2 are reflective or mirrored with respect to each other and relative to an axis (not shown) extending along a track of the double-mode surface-acoustic-wave filter 124-3. This axis can be located midway along the transversal direction or width of the double-mode surface-acoustic-wave filter 124-3. With this reflection structure, the aperture of the double-mode surface-acoustic-wave filter 124-3 has a varying width or size across the length of the double-mode surface-acoustic-wave filter 124-3. In the double-mode surface-acoustic-wave filter 124-4, the first and second parts of the apodized structure 802-1 and 802-2 are parallel with respect to each other. With this parallel structure, the aperture of the double-mode surface-acoustic-wave filter 124-4 has a constant width or size across the length of the double-mode surface-acoustic-wave filter 124-3. In other cases, the first and second parts of the apodized structure 802-1 and 802-2 may be non-parallel and non-mirrored with respect to each other.

With reference to FIG. 11-3, in example implementations, the double-mode surface-acoustic-wave filter 124-5 has an apodization function with local aperture variations that are mainly confined to the transition regions 128. This example apodized structure 802 can be employed with architectures in which relevant spurious modes are located in the transition regions 128 (two of which are shown by way of example only), to the relative exclusion of the central regions 502 (one of which is shown by way of example only), of the interdigital transducers 126-1 to 126-3.

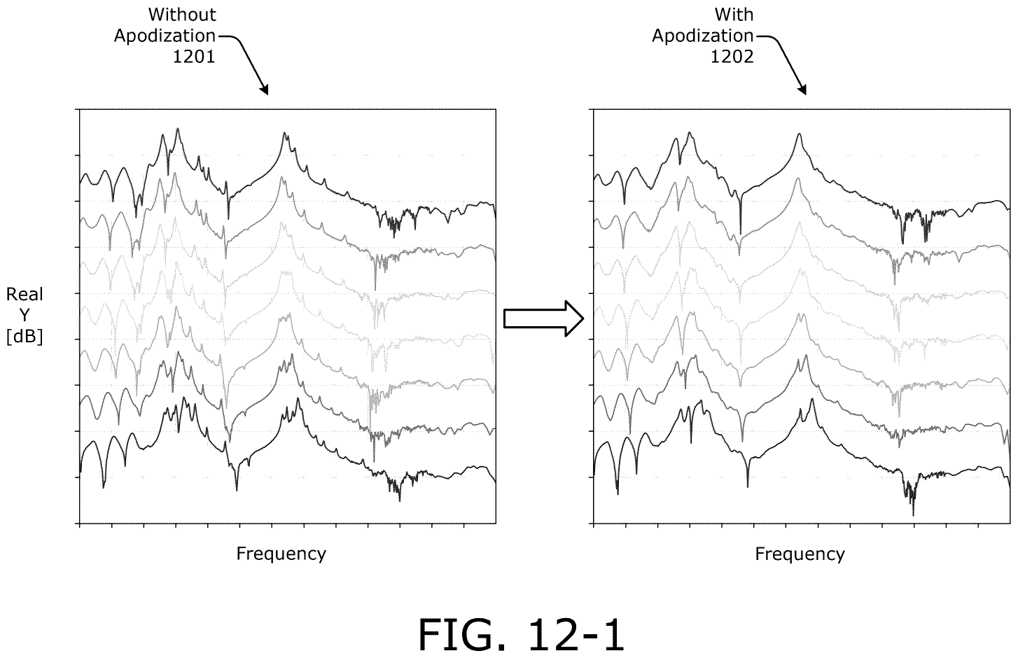

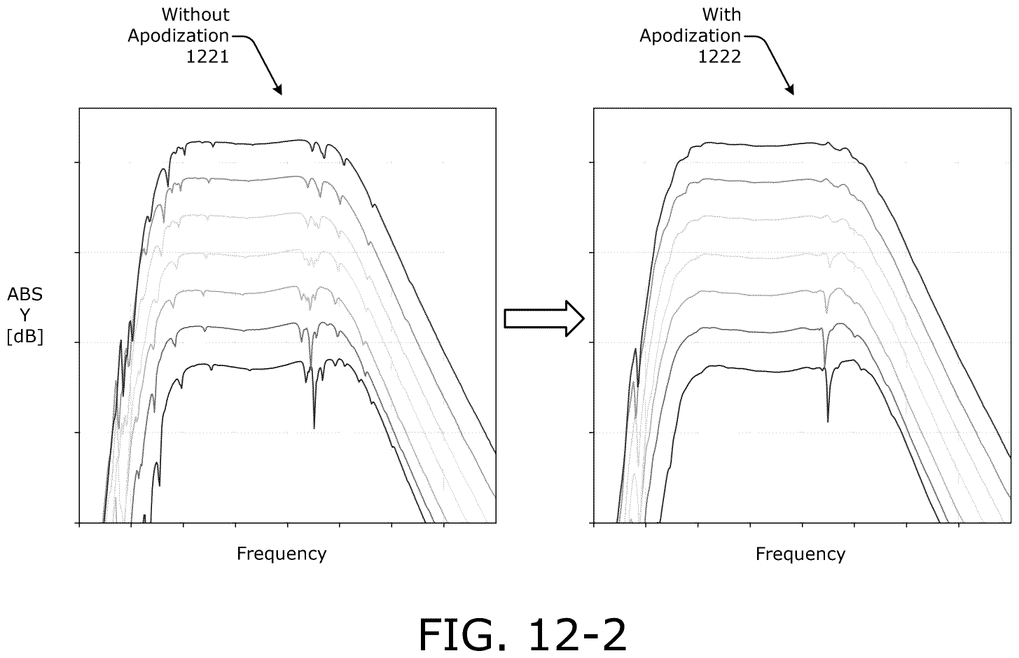

FIG. 12-1 illustrates two graphs depicting example real-admittance performance of multiple double-mode surface-acoustic-wave filters. Each graph depicts the real admittance (Real Y) in decibels versus frequency. The different performance curves in each graph correspond to different metallization ratios. The left graph corresponds to double-mode surface-acoustic-wave filters without apodization 1201. The right graph corresponds to double-mode surface-acoustic-wave filters with apodization 1202. The real-admittance performance of the with-apodization 1202 DMS filters on the right is noticeably smoother, with smaller and fewer spurious peaks and valleys, as compared to the real-admittance performance of the without-apodization 1201 DMS filters on the left.

FIG. 12-2 illustrates two graphs depicting example admittance-magnitude performance of multiple DMS filters. Each graph depicts the magnitude of the admittance (ABS Y) in decibels versus frequency. The different performance curves in each graph correspond to different metallization ratios. The left graph corresponds to double-mode surface-acoustic-wave filters without apodization 1221. The right graph corresponds to double-mode surface-acoustic-wave filters with apodization 1222. The admittance-magnitude performance of the with-apodization 1222 DMS filters on the right is noticeably smoother, with both smaller and fewer spurious peaks and valleys, as compared to the admittance-magnitude performance of the without-apodization 1221 DMS filters on the left.

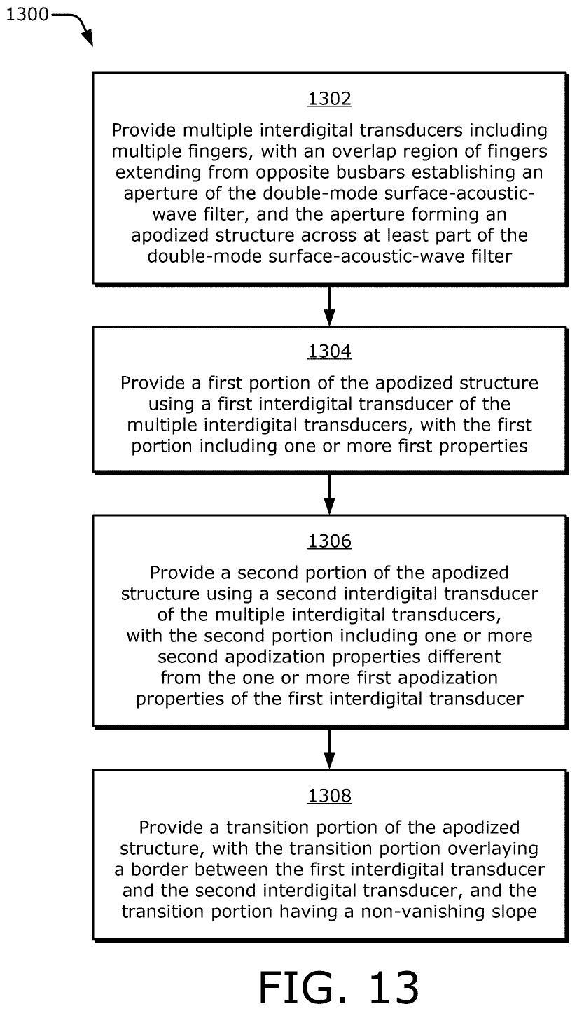

FIG. 13 is a flow diagram illustrating an example process 1300 for manufacturing a double-mode surface-acoustic-wave filter with apodization. The process 1300 is described in the form of a set of blocks 1302 to 1308 that specify operations that can be performed. However, operations are not necessarily limited to the order shown in FIG. 13 or described herein, for the operations may be implemented in alternative orders or in fully or partially overlapping manners. Also, more, fewer, and/or different operations may be implemented to perform the process 1300, or an alternative process. Operations represented by the illustrated blocks of the process 1300 may be performed to manufacture a double-mode surface-acoustic-wave filter 124 (e.g., of FIGS. 1 to 6 or 8 to 11-3).

At block 1302, multiple interdigital transducers including multiple fingers are provided, with an overlap region of fingers extending from opposite busbars establishing an aperture of the double-mode surface-acoustic-wave filter. Here, the aperture forms an apodized structure across at least part of the double-mode surface-acoustic-wave filter. For example, multiple interdigital transducers 126 including multiple fingers 312 can be provided, with an overlap region 410 of fingers 312 extending from opposite busbars 310 establishing an aperture 804 of the double-mode surface-acoustic-wave filter 124. The aperture 804 can form an apodized structure 802 across at least part of a double-mode surface-acoustic-wave filter 124. Each distal tip of each finger 312 that is disposed away from a busbar 310 to which the finger 312 is coupled may, at least partially, establish an overlap region 410 relative to at least one other finger 312 and a distal fingertip thereof. A pattern and placement of the multiple fingertips may define, at least partially, the apodized structure 802. Each finger 312 may include a first piston mode structure 702 at the distal fingertip and may further include a second piston mode structure 702 disposed nearer an originating point from the corresponding busbar 310 in alignment with the piston mode structures 702 at the fingertips of adjacent fingers 312 that extend from a different busbar 310.

At block 1304, a first portion of the apodized structure is provided using a first interdigital transducer of the multiple interdigital transducers, with the first portion including one or more first apodization properties. For example, a first portion of the apodized structure 802 can be provided using a first interdigital transducer 126-1 of the multiple interdigital transducers 126, with the first portion comprising one or more first apodization properties 130. In some cases, the first portion of the apodized structure 802 may be realized using the distal tips of fingers 312 extending from a first busbar 310 of the first interdigital transducer 126-1 relative to a resulting overlap with other fingers 312 of the first interdigital transducer 126-1.

At block 1306, a second portion of the apodized structure is provided using a second interdigital transducer of the multiple interdigital transducers, with the second portion including one or more second apodization properties different from the one or more first apodization properties of the first interdigital transducer. For example, a second portion of the apodized structure 802 can be provided using a second interdigital transducer 126-2 of the multiple interdigital transducers 126, with the second portion including one or more second apodization properties 130 different from the one or more first apodization properties 130 of the first interdigital transducer 126-1. The second interdigital transducer 126-2 may have or contribute to a phase shift 134, an amplitude 136, a combination thereof, and so forth such that the positions of the fingertips (e.g., of the piston mode structures 702 if present) of the second interdigital transducer 126-2 interface with the one or more first apodization properties 130 of the first interdigital transducer 126 to establish a continuous apodization function across the double-mode surface-acoustic-wave filter 124 while establishing an extrema or creating a desired slope 140 in a targeted interdigital transducer 126. Here, the values of the one or more second apodization properties 130 may be different from the values of the one or more first apodization properties 130 (e.g., one amplitude 136 may be greater than another or a period 132 may be longer in one interdigital transducer 126 as compared to another).

At block 1308, a transition portion of the apodized structure is provided, with the transition portion overlaying a border between the first interdigital transducer and the second interdigital transducer, and with the transition portion having a non-vanishing slope. For example, a transition portion of the apodized structure 802 can be provided, with the transition portion overlaying a border between the first interdigital transducer 126-1 and the second interdigital transducer 126-2, and with the transition portion having a non-vanishing slope 140. Thus, a non-vanishing slope 904, 924, or 1002 of a set of fingertips (e.g., which may correspond to piston mode structures 702) that are located in a transition region 128 may be created using the fingers of the first and second interdigital transducers 126-1 and 126-2. In example operations, the non-vanishing slope of the apodized structure 802, which may be created by manipulating a phase 134 or other apodization property 130 of one or more interdigital transducers, may suppress a cavity mode of the double-mode surface-acoustic-wave filter 124 to produce smoother frequency responses.

This section describes some aspects of example implementations and/or example configurations related to the apparatuses and/or processes presented above.

Example aspect 1: An apparatus comprising:
a double-mode surface-acoustic-wave filter comprising multiple interdigital transducers that comprise multiple fingers, an overlap region of fingers extending from opposite busbars establishing an aperture of the double-mode surface-acoustic-wave filter, the aperture forming an apodized structure across at least part of the double-mode surface-acoustic-wave filter, the multiple interdigital transducers comprising:
   a first interdigital transducer comprising a first portion of the apodized structure, the first portion comprising one or more first apodization properties;
   a second interdigital transducer comprising a second portion of the apodized structure, the second portion comprising one or more second apodization properties different from the one or more first apodization properties of the first interdigital transducer; and
   a transition region overlaying a border between the first interdigital transducer and the second interdigital transducer, the transition region comprising a transition portion of the apodized structure, the transition portion having a non-vanishing slope.

Example aspect 2: The apparatus of example aspect 1, wherein:
the aperture is established based on a length of the overlap region of neighboring fingers of the multiple fingers; and
the apodized structure corresponds to a local variation of the aperture.

Example aspect 3: The apparatus of example aspect 1 or 2, wherein:
each interdigital transducer of the multiple interdigital transducers comprises:
   a first busbar;
   a second busbar;
   a first set of fingers extending from the first busbar towards the second busbar; and
   a second set of fingers extending from the second busbar towards the first busbar, the first set of fingers substantially parallel to the second set of fingers; and
the overlap region is disposed between the first busbar and the second busbar where the first set of fingers overlaps the second set of fingers.

Example aspect 4: The apparatus of any one of the preceding example aspects, wherein:
an average width of the overlap region comprises the aperture of the double-mode surface-acoustic-wave filter; and
the average width is less than a product of forty (40) and a wavelength (λ) targeted by the double-mode surface-acoustic-wave filter.

Example aspect 5: The apparatus of example aspect 4, wherein:
at least one of a position or a width of the aperture varies across a length of the double-mode surface-acoustic-wave filter.

Example aspect 6: The apparatus of example aspect 4, wherein:
the average width is less than a product of twenty-five (25) and the wavelength (λ) targeted by the double-mode surface-acoustic-wave filter.

Example aspect 7: The apparatus of example aspect 4, wherein:
the wavelength (λ) targeted by the double-mode surface-acoustic-wave filter comprises a center frequency of a bandpass response of the double-mode surface-acoustic-wave filter.

Example aspect 8: The apparatus of example aspect 4, wherein:
the wavelength (λ) is substantially equal to twice a pitch of the multiple fingers.

Example aspect 9: The apparatus of any one of the preceding example aspects, wherein:
the multiple interdigital transducers comprise multiple piston mode structures, each finger of the multiple fingers comprising a piston mode structure of the multiple piston mode structures that is disposed at least proximately to a distal tip of each finger.

Example aspect 10: The apparatus of example aspect 9, wherein:
each piston mode structure of the multiple piston mode structures is disposed at the distal tip of a finger of the multiple fingers; and
each piston mode structure of the multiple piston mode structures comprises a portion of a finger of the multiple fingers with a different structure as compared to a majority portion of the finger.

Example aspect 11: The apparatus of example aspect 10, wherein:
the different structure comprises at least one of a mass difference or a shape difference configured to suppress a two-dimensional (2D) spurious mode relative to where energy of a propagating wave is located.

Example aspect 12: The apparatus of any one of the preceding example aspects, wherein:
the multiple interdigital transducers comprise multiple piston mode structures, each finger of the multiple fingers comprising a piston mode structure of the multiple piston mode structures that is disposed at least proximately to a distal tip of each finger;
the piston mode structure of the multiple piston mode structures that is disposed at least proximately to the distal tip of each finger of the multiple fingers comprises a first piston mode structure of each finger;
each finger of the multiple fingers comprises a second piston mode structure of the multiple piston mode structures, the second piston mode structure disposed at least proximately to a proximal part of each finger; and
the first piston mode structure and the second piston mode structure of each finger of the multiple fingers form the apodized structure across at least part of the double-mode surface-acoustic-wave filter.

Example aspect 13: The apparatus of example aspect 12, wherein each piston mode structure comprises at least one of:
additional metal material;
a longitudinal dielectric bar;
a hammerhead;
a flared shape; or
reduced metal material.

Example aspect 14: The apparatus of example aspect 12, wherein:
the apodized structure comprises a first set of piston mode structures that corresponds to a first function and a second set of piston mode structures that corresponds to a second function;
the first set of piston mode structures comprises the first piston mode structure of a first finger of the multiple fingers and the second piston mode structure of a second finger of the multiple fingers, the second finger adjacent to the first finger; and
the second set of piston mode structures comprises the second piston mode structure of the first finger of the multiple fingers and the first piston mode structure of a third finger of the multiple fingers, the third finger adjacent to the first finger.

Example aspect 15: The apparatus of example aspect 14, wherein:
the first function is substantially parallel to the second function.

Example aspect 16: The apparatus of example aspect 14, wherein:
the first function is substantially reflective or mirrored with respect to the second function relative to an axis extending along a track of the double-mode surface-acoustic-wave filter.

Example aspect 17: The apparatus of example aspect 14, wherein:
the first function is non-parallel and non-mirrored with respect to the second function.

Example aspect 18: The apparatus of example aspect 14, wherein:
the first interdigital transducer comprises a first busbar, a second busbar, the first finger, the second finger, and the third finger;
the first finger extends from the first busbar towards the second busbar;
the second finger extends from the second busbar towards the first busbar; and
the third finger extends from the second busbar towards the first busbar.

Example aspect 19: The apparatus of any one of the preceding example aspects, wherein:
the double-mode surface-acoustic-wave filter comprises a piezoelectric layer coupled to the multiple interdigital transducers; and
the piezoelectric layer comprises a high coupling (k²) material.

Example aspect 20: The apparatus of example aspect 19, wherein:
the high coupling (k²) material has a coupling coefficient approximately between 5% and 20%.

Example aspect 21: The apparatus of any one of the preceding example aspects, wherein:
the double-mode surface-acoustic-wave filter comprises two reflectors;
the multiple interdigital transducers have quantity of at least three (3); and
the multiple interdigital transducers are disposed between the two reflectors along a length of the double-mode surface-acoustic-wave filter.

Example aspect 22: The apparatus of example aspect 21, wherein:
the double-mode surface-acoustic-wave filter has a first side and a second side, the first side separated from the second side by a width of the double-mode surface-acoustic-wave filter;
the first interdigital transducer is adjacent to the second interdigital transducer;
the first interdigital transducer has an input port on the first side and a ground port on the second side; and
the second interdigital transducer has a ground port on the first side and an output port on the second side.

Example aspect 23: The apparatus of any one of the preceding example aspects, wherein:
the non-vanishing slope is greater than approximately three degrees (3°).

Example aspect 24: The apparatus of example aspect 23, wherein:
the non-vanishing slope is greater than approximately ten degrees (10°).

Example aspect 25: The apparatus of any one of the preceding example aspects, wherein:
each interdigital transducer of the multiple interdigital transducers comprises a central region; and
each portion of the apodized structure within the central region of each interdigital transducer of the multiple interdigital transducers has a non-vanishing slope.

Example aspect 26: The apparatus of any one of the preceding example aspects, wherein:
the one or more first apodization properties comprise a first phase;
the one or more second apodization properties comprise a second phase; and
the first phase is different from the second phase.

Example aspect 27: The apparatus of example aspect 26, wherein:
a difference between the first phase and the second phase establishes a phase shift of the apodized structure at the transition portion; and
the phase shift is configured to cause the transition portion to have the non-vanishing slope.

Example aspect 28: The apparatus of any one of the preceding example aspects, wherein:
the one or more first apodization properties and the one or more second apodization properties comprise at least one of an amplitude, a period, or a phase.

Example aspect 29: The apparatus of any one of the preceding example aspects, wherein:
an apodization property of the one or more first apodization properties or the one or more second apodization properties comprises an amplitude of at least one portion of the apodized structure; and
the amplitude has a value between approximately five percent (5%) and thirty percent (30%) of the aperture of the double-mode surface-acoustic-wave filter.

Example aspect 30: The apparatus of any one of the preceding example aspects, wherein:
an apodization property of the one or more first apodization properties or the one or more second apodization properties comprises a period property of at least one portion of the apodized structure; and
the period property has a value between approximately half (0.5) and one (1) period per length of each interdigital transducer of the multiple interdigital transducers.

Example aspect 31: The apparatus of any one of the preceding example aspects, wherein:
an apodization property relating to at least one of the one or more first apodization properties or the one or more second apodization properties comprises a phase shift between at least two portions of the apodized structure; and
the phase shift has a value between approximately zero degrees (0°) and ninety degrees (90°) of a period per length of each interdigital transducer of the multiple interdigital transducers.

Example aspect 32: An apparatus comprising:
a double-mode surface-acoustic-wave filter comprising multiple interdigital transducers, the multiple interdigital transducers comprising multiple fingers, the multiple fingers having various lengths to form an apodized structure across at least part of the double-mode surface-acoustic-wave filter, the multiple interdigital transducers comprising:
   a first interdigital transducer comprising a first portion of the apodized structure, the first portion comprising one or more first apodization properties;
   a second interdigital transducer comprising a second portion of the apodized structure, the second portion comprising one or more second apodization properties different from the one or more first apodization properties; and
   a transition region overlaying a border between the first interdigital transducer and the second interdigital transducer, the transition region comprising a transition portion of the apodized structure, the transition portion including a phase shift of the apodized structure.

Example aspect 33: The apparatus of example aspect 32, wherein:
the one or more first apodization properties comprise a first phase;
the one or more second apodization properties comprise a second phase;
the first phase is different from the second phase; and
a difference between the first phase and the second phase establishes the phase shift of the apodized structure at the transition portion.

Example aspect 34: The apparatus of example aspect 32 or 33, wherein:
the phase shift of the apodized structure is configured to suppress a cavity mode of the double-mode surface-acoustic-wave filter.

Example aspect 35: The apparatus of any one of example aspects 32-34, wherein:
the double-mode surface-acoustic-wave filter comprises a piezoelectric layer coupled to the multiple interdigital transducers; and
the piezoelectric layer comprises lithium niobate (LiNbO3) having a cut approximately between 145° and 180°.

Example aspect 36: A method of manufacturing a double-mode surface-acoustic-wave filter, the method comprising:
providing multiple interdigital transducers comprising multiple fingers, an overlap region of fingers extending from opposite busbars establishing an aperture of the double-mode surface-acoustic-wave filter, the aperture forming an apodized structure across at least part of the double-mode surface-acoustic-wave filter;
providing a first portion of the apodized structure using a first interdigital transducer of the multiple interdigital transducers, the first portion comprising one or more first apodization properties;
providing a second portion of the apodized structure using a second interdigital transducer of the multiple interdigital transducers, the second portion comprising one or more second apodization properties different from the one or more first apodization properties of the first interdigital transducer; and
providing a transition portion of the apodized structure, the transition portion overlaying a border between the first interdigital transducer and the second interdigital transducer, the transition portion having a non-vanishing slope.

As used herein, the terms “couple,” “coupled,” or “coupling” refer to a relationship between two or more components that are in operative communication with each other to implement some feature or realize some capability that is described herein. The coupling can be realized using, for instance, a galvanic coupling, such as a physical line (e.g., a metal trace or wire) or an electromagnetic coupling, such as with a transformer. A coupling can include a direct coupling or an indirect coupling. A direct coupling refers to connecting discrete circuit elements via a same node without an intervening element. An indirect coupling refers to connecting discrete circuit elements via one or more other devices or other discrete circuit elements, including two or more different nodes.

The term “node” (e.g., including a “first node” or an “input node”) represents at least a point of electrical connection between two or more components (e.g., circuit elements). Although at times a node may be visually depicted in a drawing as a single point, the node can represent a connection portion of a physical circuit or network that has approximately a same voltage potential at or along the connection portion between two or more components. In other words, a node can represent at least one of multiple points along a conducting medium (e.g., a wire or trace) that exists between electrically connected components. Similarly, a “terminal” or “port” may represent one or more points with at least approximately a same voltage potential relative to an input or output of a component (e.g., a mixer). In this context, a same voltage potential can pertain to two voltages that may differ from impacts caused by a conducting medium (e.g., a parasitic effect) but that do not differ due to impacts arising from an intervening architected component.

The terms “first,” “second,” “third,” and other numeric-related indicators are used herein to identify or distinguish similar or analogous items from one another within a given context—such as a particular implementation, a single drawing figure, a given component, or a claim. Thus, a first item in one context may differ from a first item in another context. For example, an item identified as a “first interdigital transducer” in one context may be identified as a “second interdigital transducer” in another context. Similarly, a “first set of fingers” or a “first apodization property” in one claim may be recited as a “second set of fingers” or a “third apodization property,” respectively, in a different claim. Additionally, a “first portion of an apodized structure” in one claim may be different from (e.g., part of a different interdigital transducer or having a different property as compared to) a “first portion of an apodized structure” in another claim.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Finally, although subject matter has been described in language specific to structural features or methodological operations, it is to be understood that the subject matter defined in the appended claims is not necessarily limited to the specific features or operations described above. This includes not necessarily being limited to the organizations or combinations in which features are arranged or the orders in which operations are performed. Rather, the specific features and methods are disclosed as example implementations for realizing a double-mode surface-acoustic-wave (SAW) filter with apodization.

What is claimed is:

1. An apparatus comprising:
a double-mode surface-acoustic-wave filter comprising multiple interdigital transducers that comprise multiple fingers, an overlap region of fingers extending from opposite busbars establishing an aperture of the double-mode surface-acoustic-wave filter, the aperture forming an apodized structure across at least part of the double-mode surface-acoustic-wave filter, the multiple interdigital transducers comprising:
a first interdigital transducer comprising a first portion of the apodized structure, the first portion comprising one or more first apodization properties;
a second interdigital transducer comprising a second portion of the apodized structure, the second portion comprising one or more second apodization properties different from the one or more first apodization properties of the first interdigital transducer; and
a transition region overlaying a border between the first interdigital transducer and the second interdigital transducer, the transition region comprising a transition portion of the apodized structure, the transition portion having a non-vanishing slope.

2. The apparatus of claim 1, wherein:
the aperture is established based on a length of the overlap region of neighboring fingers of the multiple fingers; and
the apodized structure corresponds to a local variation of the aperture.

3. The apparatus of claim 1, wherein:
each interdigital transducer of the multiple interdigital transducers comprises:
a first busbar;
a second busbar;
a first set of fingers extending from the first busbar towards the second busbar; and
a second set of fingers extending from the second busbar towards the first busbar, the first set of fingers substantially parallel to the second set of fingers; and
the overlap region is disposed between the first busbar and the second busbar where the first set of fingers overlaps the second set of fingers.

4. The apparatus of claim 3, wherein:
an average width of the overlap region comprises the aperture of the double-mode surface-acoustic-wave filter; and
the average width is less than a product of forty (40) and a wavelength (λ) targeted by the double-mode surface-acoustic-wave filter.

5. The apparatus of claim 4, wherein:
at least one of a position or a width of the aperture varies across a length of the double-mode surface-acoustic-wave filter.

6. The apparatus of claim 1, wherein:
the multiple interdigital transducers comprise multiple piston mode structures, each finger of the multiple fingers comprising a piston mode structure of the multiple piston mode structures that is disposed at least proximately to a distal tip of each finger.

7. The apparatus of claim 1, wherein:
the multiple interdigital transducers comprise multiple piston mode structures, each finger of the multiple fingers comprising a piston mode structure of the multiple piston mode structures that is disposed at least proximately to a distal tip of each finger;
the piston mode structure of the multiple piston mode structures that is disposed at least proximately to the distal tip of each finger of the multiple fingers comprises a first piston mode structure of each finger;
each finger of the multiple fingers comprises a second piston mode structure of the multiple piston mode structures, the second piston mode structure disposed at least proximately to a proximal part of each finger; and
the first piston mode structure and the second piston mode structure of each finger of the multiple fingers form the apodized structure across at least part of the double-mode surface-acoustic-wave filter.

8. The apparatus of claim 7, wherein:
the apodized structure comprises a first set of piston mode structures that corresponds to a first function and a second set of piston mode structures that corresponds to a second function;
the first set of piston mode structures comprises the first piston mode structure of a first finger of the multiple fingers and the second piston mode structure of a second finger of the multiple fingers, the second finger adjacent to the first finger; and
the second set of piston mode structures comprises the second piston mode structure of the first finger of the multiple fingers and the first piston mode structure of a third finger of the multiple fingers, the third finger adjacent to the first finger.

9. The apparatus of claim 1, wherein:
the double-mode surface-acoustic-wave filter comprises a piezoelectric layer coupled to the multiple interdigital transducers; and
the piezoelectric layer comprises a high coupling (k²) material.

10. The apparatus of claim 1, wherein:
the non-vanishing slope is greater than approximately three degrees (3°).

11. The apparatus of claim 1, wherein:
each interdigital transducer of the multiple interdigital transducers comprises a central region; and
each portion of the apodized structure within the central region of each interdigital transducer of the multiple interdigital transducers has a non-vanishing slope.

12. The apparatus of claim 1, wherein:
the one or more first apodization properties comprise a first phase;
the one or more second apodization properties comprise a second phase; and
the first phase is different from the second phase.

13. The apparatus of claim 12, wherein:
a difference between the first phase and the second phase establishes a phase shift of the apodized structure at the transition portion; and
the phase shift is configured to cause the transition portion to have the non-vanishing slope.

14. The apparatus of claim 1, wherein:
an apodization property of the one or more first apodization properties or the one or more second apodization properties comprises an amplitude of at least one portion of the apodized structure; and
the amplitude has a value between approximately five percent (5%) and thirty percent (30%) of the aperture of the double-mode surface-acoustic-wave filter.

15. The apparatus of claim 1, wherein:
an apodization property of the one or more first apodization properties or the one or more second apodization properties comprises a period property of at least one portion of the apodized structure; and
the period property has a value between approximately half (0.5) and one (1) period per length of each interdigital transducer of the multiple interdigital transducers.

16. The apparatus of claim 1, wherein:
an apodization property relating to at least one of the one or more first apodization properties or the one or more second apodization properties comprises a phase shift between at least two portions of the apodized structure; and
the phase shift has a value between approximately zero degrees (0°) and ninety degrees (90°) of a period per length of each interdigital transducer of the multiple interdigital transducers.

17. An apparatus comprising:
a double-mode surface-acoustic-wave filter comprising multiple interdigital transducers, the multiple interdigital transducers comprising multiple fingers, the multiple fingers having various lengths to form an apodized structure across at least part of the double-mode surface-acoustic-wave filter, the multiple interdigital transducers comprising:
a first interdigital transducer comprising a first portion of the apodized structure, the first portion comprising one or more first apodization properties;
a second interdigital transducer comprising a second portion of the apodized structure, the second portion comprising one or more second apodization properties different from the one or more first apodization properties; and
a transition region overlaying a border between the first interdigital transducer and the second interdigital transducer, the transition region comprising a transition portion of the apodized structure, the transition portion including a phase shift of the apodized structure.

18. The apparatus of claim 17, wherein:
the one or more first apodization properties comprise a first phase;
the one or more second apodization properties comprise a second phase;
the first phase is different from the second phase; and
a difference between the first phase and the second phase establishes the phase shift of the apodized structure at the transition portion.

19. The apparatus of claim 17, wherein:
the phase shift of the apodized structure is configured to suppress a cavity mode of the double-mode surface-acoustic-wave filter.

20. A method of manufacturing a double-mode surface-acoustic-wave filter, the method comprising:
providing multiple interdigital transducers comprising multiple fingers, an overlap region of fingers extending from opposite busbars establishing an aperture of the double-mode surface-acoustic-wave filter, the aperture forming an apodized structure across at least part of the double-mode surface-acoustic-wave filter;
providing a first portion of the apodized structure using a first interdigital transducer of the multiple interdigital transducers, the first portion comprising one or more first apodization properties;
providing a second portion of the apodized structure using a second interdigital transducer of the multiple interdigital transducers, the second portion comprising one or more second apodization properties different from the one or more first apodization properties of the first interdigital transducer; and
providing a transition portion of the apodized structure, the transition portion overlaying a border between the first interdigital transducer and the second interdigital transducer, the transition portion having a non-vanishing slope.
